(19) United States
(12) Patent Application Publication
(10) Pub. No.: US 2026/0371875 A1
(43) Pub. Date: Nov. 19, 2026

(54) DISPLAY DEVICE AND ELECTRONIC DEVICE INCLUDING THE SAME

(71) Applicant: Samsung Display Co., Ltd., Yongin-si (KR)

(72) Inventors: YUNMI KIM, Yongin-si (KR); DOYEONG PARK, Yongin-si (KR); DONG HEE SHIN, Yongin-si (KR); HYEONGSEOK KIM, Yongin-si (KR)

(21) Appl. No.: 19/640,720

(22) Filed: Apr. 7, 2026

(30) Foreign Application Priority Data
May 13, 2025 (KR) 10-2025-0062099

(51) Int. Cl. H10K 59/131; H10K 59/121; H10K 59/35

(52) U.S. Cl. CPC H10K 59/131; H10K 59/1213; H10K 59/353

(57) ABSTRACT

A display device includes a pixel unit including a first red light-emitting element, a first-first green light-emitting element, a second blue light-emitting element, and a second-second green light-emitting element, which are located in a first light-emitting element row, and a first blue light-emitting element, a first-second green light-emitting element, a second red light-emitting element, and a second-first green light-emitting element, which are located in a second light-emitting element row. The first red light-emitting element, the first-first green light-emitting element, the second blue light-emitting element, and the second-second green light-emitting element are electrically connected to a first gate write line. The first blue light-emitting element, the first-second green light-emitting element, the second red light-emitting element, and the second-first green light-emitting element are electrically connected to a second gate write line.

### CROSS-REFERENCE TO RELATED APPLICATION

The present application claims priority to and the benefit of Korean Patent Application No. 10-2025-0062099, filed on May 13, 2025, in the Korean Intellectual Property Office, the entire disclosure of which is incorporated by reference herein.

### BACKGROUND

### 1. Field

Aspects of embodiments of the present disclosure relate to a display device.

### 2. Description of the Related Art

Organic light-emitting display apparatus includes a display element, for example, such an organic light-emitting diode (OLED), of which the brightness varies with a current.

### SUMMARY

Embodiments of the present disclosure may be directed to a display device capable of reducing a visibility due to a difference in brightness.

According to one or more embodiments of the present disclosure, a display device includes: a substrate; a plurality of pixel units arranged in a matrix on the substrate, each of the plurality of pixel units including a plurality of light-emitting elements and a plurality of pixel circuits electrically connected to the light-emitting elements, respectively; and a plurality of gate write lines on the substrate, and including a first gate write line and a second gate write line. Each of the plurality of pixel units includes a first pixel unit and a second pixel unit adjacent to each other in a first direction. The first pixel unit includes a first red light-emitting element, a first-first green light-emitting element, a first blue light-emitting element, and a first-second green light-emitting element from among the plurality of light-emitting elements, the first red light-emitting element and the first-first green light-emitting element being located in a first light-emitting element row, and the first blue light-emitting element and the first-second green light-emitting element being located in a second light-emitting element row. The second pixel unit includes a second blue light-emitting element, a second-second green light-emitting element, a second red light-emitting element, and a second-first green light-emitting element from among the plurality of light-emitting elements, the second blue light-emitting element and the second-second green light-emitting element being located in the first light-emitting element row, and the second red light-emitting element and the second-first green light-emitting element being located in the second light-emitting element row. The first gate write line and the second gate write line are adjacent to each other, and cross each of the plurality of pixel units in the first direction. The first red light-emitting element, the first-first green light-emitting element, the second blue light-emitting element, and the second-second green light-emitting element are electrically connected to the first gate write line. The first blue light-emitting element, the first-second green light-emitting element, the second red light-emitting element, and the second-first green light-emitting element are electrically connected to the second gate write line.

In an embodiment, in a plan view, an arrangement pattern of the plurality of light-emitting elements included in each of the plurality of pixel units on the substrate may be different from an arrangement pattern of the plurality of pixel circuits included in each of the plurality of pixel units on the substrate.

In an embodiment, an arrangement of the light-emitting elements included in the second pixel unit may correspond to an arrangement of the light-emitting elements included in the first pixel unit that is rotated by 180 degrees clockwise with respect to a virtual axis, and is then flipped left and right around an axis parallel to the virtual axis, the virtual axis dividing the first pixel unit from the second pixel unit and extending in a second direction crossing the first direction.

In an embodiment, a green light-emitting element may be located at each of vertices of an imaginary square having, as a center point thereof, a center point of a red light-emitting element or a blue light-emitting element in each of the plurality of pixel units.

In an embodiment, a size of a light-emitting region of each of the red light-emitting element and the blue light-emitting element may be larger than a size of a light-emitting region of the green light-emitting element.

In an embodiment, in a plan view, at least one pixel circuit included in each of the plurality of pixel units may not overlap with a light-emitting element electrically connected to the at least one pixel circuit.

In an embodiment, the first-second green light-emitting element may not overlap with a first-second green pixel circuit that is electrically connected to the first-second green light-emitting element and configured to drive the first-second green light-emitting element from among the plurality of pixel circuits; and the second-second green light-emitting element may not overlap with a second-second green pixel circuit that is electrically connected to the second-second green light-emitting element and configured to drive the second-second green light-emitting element from among the plurality of pixel circuits.

In an embodiment, the plurality of pixel circuits included in each of the plurality of pixel units may be located in a row in the first direction.

In an embodiment, a ratio of a width of a pixel circuit area in the first direction to a length of the pixel circuit area in the second direction may be 1:8, the pixel circuit area being occupied by a pixel circuit from among the plurality of pixel circuits included in each of the plurality of pixel units.

In an embodiment, in each of the plurality of pixel units, a brightness of the second-first green light-emitting element in the first light-emitting element row may be higher than a brightness of remaining light-emitting elements from among the plurality of light-emitting elements in the first light-emitting element row.

In an embodiment, in each of the plurality of pixel units, a brightness of the second-second green light-emitting element in the second light-emitting element row may be lower than a brightness of remaining light-emitting elements from among the plurality of light-emitting elements in the second light-emitting element row.

In an embodiment, in each of the plurality of pixel units, a brightness of the second-first green light-emitting element in the first light-emitting element row may be higher than a brightness of the second-second green light-emitting element in the second light-emitting element row.

In an embodiment, the first gate write line may be configured to be applied with a gate write signal first, and the second gate write line may be configured to be applied with another gate write signal after the gate write signal is applied to the first gate write line.

In an embodiment, the display device may further include a plurality of data lines on the substrate, and including a first data line configured to transmit a first data signal, a second data line configured to transmit a second data signal, a third data line configured to transmit a third data signal, and a fourth data line configured to transmit a fourth data signal, the first to fourth data lines extending in a second direction crossing the first direction. In each of the plurality of pixel units: the first red light-emitting element and the first blue light-emitting element may be configured to emit light in response to the first data signal; the first-first green light-emitting element and the first-second green light-emitting element may be configured to emit light in response to the second data signal; the second red light-emitting element and the second blue light-emitting element may be configured to emit light in response to the third data signal; and the second-first green light-emitting element and the second-second green light-emitting element may be configured to emit light in response to the fourth data signal.

In an embodiment, the first data line and the second data line may extend in the second direction at least between the first red light-emitting element and the first blue light-emitting element and the first-first green light-emitting element and the first-second green light-emitting element; and the third data line and the fourth data line may extend in the second direction between the second blue light-emitting element and the second red light-emitting element and the second-first green light-emitting element and the second-second green light-emitting element.

In an embodiment, the display device may further include a gate initialization line, a gate reset line, a first emission control line, and a second emission control line extending in the first direction on the substrate. The gate initialization line, the gate reset line, the first emission control line, and the second emission control line may be commonly located in the plurality of pixel units.

According to one or more embodiments of the present disclosure, an electronic device includes: a substrate; a plurality of pixel units arranged in a matrix on the substrate, each of the plurality of pixel units including a plurality of light-emitting elements and a plurality of pixel circuits electrically connected to the light-emitting elements, respectively; a plurality of gate write lines on the substrate, and including a first gate write line and a second gate write line; a controller configured to apply a signal to the pixel circuits; and a power module configured to supply power to the controller. Each of the plurality of pixel units includes a first pixel unit and a second pixel unit adjacent to each other in a first direction. The first pixel unit includes a first red light-emitting element, a first-first green light-emitting element, a first blue light-emitting element, and a first-second green light-emitting element from among the plurality of light-emitting elements, the first red light-emitting element and the first-first green light-emitting element being located in a first light-emitting element row, and the first blue light-emitting element and the first-second green light-emitting element being located in a second light-emitting element row. The second pixel unit includes a second blue light-emitting element, a second-second green light-emitting element, a second red light-emitting element, and a second-first green light-emitting element from among the plurality of light-emitting elements, the second blue light-emitting element and the second-second green light-emitting element being located in the first light-emitting element row, and the second red light-emitting element and the second-first green light-emitting element being located in the second light-emitting element row. The first gate write line and the second gate write line are adjacent to each other, and cross each of the plurality of pixel units in the first direction. The first red light-emitting element, the first-first green light-emitting element, the second blue light-emitting element, and the second-second green light-emitting element are electrically connected to the first gate write line. The first blue light-emitting element, the first-second green light-emitting element, the second red light-emitting element, and the second-first green light-emitting element are electrically connected to the second gate write line.

In an embodiment, in each of the plurality of pixel units, a brightness of the second-first green light-emitting element in the first light-emitting element row may be higher than a brightness of remaining light-emitting elements from among the plurality of light emitting elements in the first light-emitting element row.

In an embodiment, in each of the plurality of pixel units, a brightness of the second-second green light-emitting element in the second light-emitting element row may be lower than a brightness of remaining light-emitting elements from among the plurality of light emitting elements in the second light-emitting element row.

In an embodiment, in each of the plurality of pixel units, a brightness of the second-first green light-emitting element in the first light-emitting element row may be higher than a brightness of the second-second green light-emitting element in the second light-emitting element row.

However, the present disclosure is not limited to the above aspects and features, and the above and additional aspects and features will be set forth, in part, in the detailed description that follows with reference to the drawings, and in part, may be apparent therefrom, or may be learned by practicing one or more of the presented embodiments of the present disclosure.

### BRIEF DESCRIPTION OF THE DRAWINGS

The above and other aspects and features of the present disclosure will be more clearly understood from the following detailed description of the illustrative, non-limiting embodiments with reference to the accompanying drawings, in which:

FIG. 1 is a perspective view illustrating a display device according to an embodiment;

FIG. 2 is a cross-sectional view of a display device according to an embodiment;

FIG. 3 is a plan view of a display panel of a display device according to an embodiment;

FIG. 4 is a block diagram illustrating a display panel and a display driver according to an embodiment;

FIG. 5 is a circuit diagram of a pixel of a display device according to an embodiment;

FIG. 6 is a plan view illustrating an arrangement of light-emitting elements of a display device according to an embodiment;

FIG. 7 is a plan view illustrating an arrangement of pixel circuits of a display device according to an embodiment;

FIG. 8 is a plan view illustrating both an arrangement of pixel circuits and an arrangement of light-emitting elements in a display device according to an embodiment.

FIG. 9A schematically illustrates a display area of a display device according to a comparative example;

FIG. 9B schematically illustrates a display area of a display device according to an embodiment of the present disclosure;

FIG. 10 is a schematic plan view illustrating pixel circuits included in a pixel unit of FIG. 8 according to an embodiment of the present disclosure;

FIG. 11A is a plan view illustrating a first active layer among the components in FIG. 10;

FIG. 11B is a plan view illustrating a first gate layer among the components in FIG. 10;

FIG. 11C is a plan view illustrating a second gate layer among the components in FIG. 10;

FIG. 11D is a plan view illustrating a second active layer among the components in FIG. 10;

FIG. 11E is a plan view illustrating the second active layer and a third gate layer among the components in FIG. 10;

FIG. 11F is a plan view illustrating the third gate layer and a first source/drain layer among the components in FIG. 10;

FIG. 11G is a plan view illustrating a second source/drain layer among the components in FIG. 10;

FIG. 12 is a cross-sectional view illustrating some transistors and capacitors among the components in FIG. 10;

FIG. 13 is a block diagram of an electronic device according to an embodiment; and

FIG. 14 is a schematic diagram illustrating some electronic devices according to some embodiments.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

Further, as would be understood by a person having ordinary skill in the art, in view of the present disclosure in its entirety, each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner, unless otherwise stated or implied.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature’s relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Further, it should be expected that the shapes shown in the figures may vary in practice depending, for example, on tolerances and/or manufacturing techniques. Accordingly, the embodiments of the present disclosure should not be construed as being limited to the specific shapes shown in the figures, and should be construed considering changes in shapes that may occur, for example, as a result of manufacturing. As such, the shapes shown in the drawings may not depict the actual shapes of areas of the device, and the present disclosure is not limited thereto.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being "electrically connected" to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” "includes," "including," "has," "have," and "having," when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression "A and/or B" denotes A, B, or A and B. Expressions such as “at least one of,” when preceding a list of elements, modify the entire list of elements and do not modify the individual elements of the list. For example, the expression "at least one of a, b, or c," “at least one of a, b, and c,” and “at least one selected from the group consisting of a, b, and c” indicates only a, only b, only c, both a and b, both a and c, both b and c, all of a, b, and c, or variations thereof.

As used herein, the term "substantially," "about," and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms "use," "using," and "used" may be considered synonymous with the terms "utilize," "utilizing," and "utilized," respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

As used herein, a "line" may refer to "wiring."

As used herein, the term "horizontal" may indicate that a target straight line extends in a first direction (e.g., the x-axis direction) that is the same as the first direction in which a reference straight line extends. The term "vertical" may indicate that a target straight line extends in a second direction (e.g., the y-axis direction) that intersects or crosses the reference straight line extending in the first direction (the x-axis direction).

As used herein, the terms "red light-emitting element," "green light-emitting element," or "blue light-emitting element" may refer to a light-emitting element including a pixel electrode, a light-emitting layer, and a common electrode as an electronic element, and may also refer to a light-emitting region that emits light of a certain color or an opening region defined by a pixel defining film.

As used herein, the terms "red pixel circuit," "green pixel circuit," or "blue pixel circuit" may refer to a structure, which includes at least two transistors, at least one capacitor, and a wiring connected thereto, and is electrically connected to a light-emitting element to drive the light-emitting element, and may also refer to a region in which the structure is arranged on a substrate.

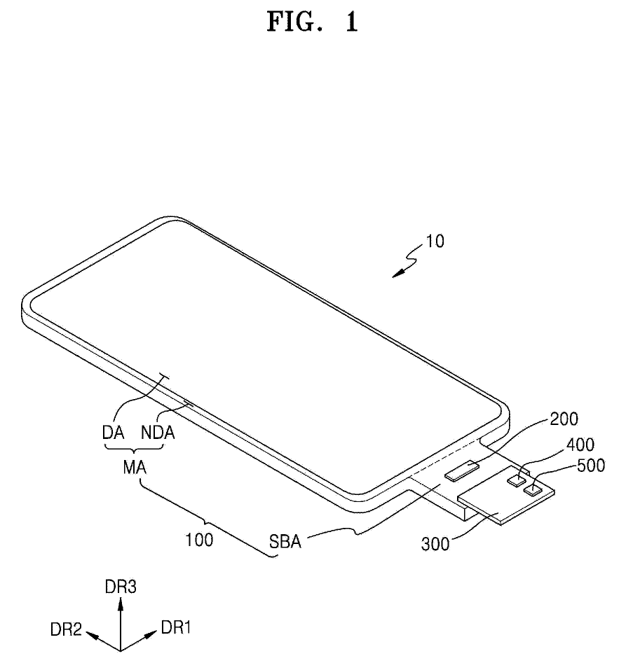

FIG. 1 is a perspective view illustrating a display device according to an embodiment.

Referring to FIG. 1, a display device 10 may be applied to portable electronic devices, such as a mobile phone, a smartphone, a tablet personal computer (PC), a mobile communication terminal, an electronic notebook, an electronic book, a portable multimedia player (PMP), a navigation device, an ultra-mobile PC (UMPC), and the like. For example, the display device 10 may be used as a display unit (e.g., a display or a display layer) of a television, a laptop computer, a monitor, a billboard, or an Internet-of-things (IOT) device. For example, the display device 10 may be applied to wearable devices, such as a smart watch, a watch phone, a glasses-type display, and a head mounted display (HMD).

The display device 10 may have a planar shape similar to that of a tetragon. For example, the display device 10 may have a planar shape similar to that of a tetragon having a short side extending in a first direction DR1 and a long side extending in a second direction DR2. A corner where a short side extending in the first direction DR1 and a long side extending in the second direction DR2 meet each other may be formed to be rounded to have a suitable curvature (e.g., a certain or predetermined curvature), or may be formed at a right angle. The planar shape of the display device 10 is not limited to that of a tetragon, and may be similarly shaped as that of another polygon, a circle, or an oval.

The display device 10 may include a display panel 100, a display driver 200, a circuit board 300, a touch driver 400, and a power supply unit (e.g., a power supply or a power supply circuit) 500.

The display panel 100 may include a main area MA and a sub-area SBA.

The main area MA may include a display area DA, which includes pixels for displaying an image, and a non-display area NDA arranged around the display area DA. The display area DA may emit light from a plurality of light-emitting regions or a plurality of opening regions. For example, the display panel 100 may include a pixel circuit including switching elements, a pixel defining film defining a light-emitting region or an opening region, and a self-light-emitting element.

For example, the self-light-emitting element may include, but is not limited to, at least one of an organic light-emitting diode (OLED) including an organic light-emitting layer, a quantum dot LED including a quantum dot light-emitting layer, an inorganic LED including an inorganic semiconductor, and/or a micro LED.

The non-display area NDA may be disposed outside the display area DA. The non-display area NDA may be defined as an edge area of the main area MA of the display panel 100. The non-display area NDA may include a gate driver, which supplies gate signals to gate lines, and fan-out lines, which connect the display driver 200 to the display area DA.

The sub-area SBA may extend from one side of the main area MA. The sub-area SBA may include a flexible material capable of bending, folding, and/or rolling. For example, when the sub-area SBA is bent, the sub-area SBA may overlap with the main area MA in a thickness direction (e.g., a third direction DR3). The sub-area SBA may include the display driver 200, and a pad unit (e.g., a pad or a pad terminal) connected to the circuit board 300. Optionally, the sub-area SBA may be omitted as needed or desired, and the display driver 200 and the pad unit may be arranged in the non-display area NDA.

The display driver 200 may output signals and voltages for driving the display panel 100. The display driver 200 may supply data voltages to data lines. The display driver 200 may provide a power supply voltage to a power line, and may supply a gate control signal to a gate driver. The display driver 200 may be formed as an integrated circuit (IC), and may be mounted on the display panel 100 by using a chip-on-glass (COG) method, a chip-on-plastic (COP) method, or an ultrasonic bonding method. For example, the display driver 200 may be arranged in the sub-area SBA, and may overlap with the main area MA in the thickness direction (e.g., the third direction DR3) by the bending of the sub-area SBA. As another example, the display driver 200 may be mounted on the circuit board 300.

The circuit board 300 may be attached to the pad unit of the display panel 100 by using an anisotropic conductive film (ACF). Lead lines of the circuit board 300 may be electrically connected to the pad unit of the display panel 100. The circuit board 300 may be a flexible printed circuit board, a printed circuit board, or a flexible film such as a chip-on-film.

The touch driver 400 may be mounted on the circuit board 300. The touch driver 400 may be electrically connected to a touch sensing unit (e.g., a touch sensor or a touch sensing layer) of the display panel 100. The touch driver 400 may supply a touch driving signal to a plurality of touch electrodes of the touch sensing unit, and may sense an electrostatic capacitance variance of the touch electrodes. For example, the touch driving signal may include a pulse signal having a suitable frequency (e.g., a certain or predetermined frequency). The touch driver 400 may detect an input, and may calculate coordinates of the input based on an electrostatic capacitance variance of the plurality of touch electrodes. The touch driver 400 may be formed as an IC.

The power supply unit 500 may be arranged on the circuit board 300, and may provide a power supply voltage to the display driver 200 and the display panel 100. The power supply unit 500 may generate and supply a driving voltage to a driving voltage line, may generate and supply an initialization voltage to an initialization voltage line, and may generate and supply a common voltage to a common electrode that is common to the light-emitting elements of the plurality of pixels. For example, the driving voltage may include a high-potential voltage for driving a light-emitting element, and the common voltage may include a low-potential voltage for driving the light-emitting element.

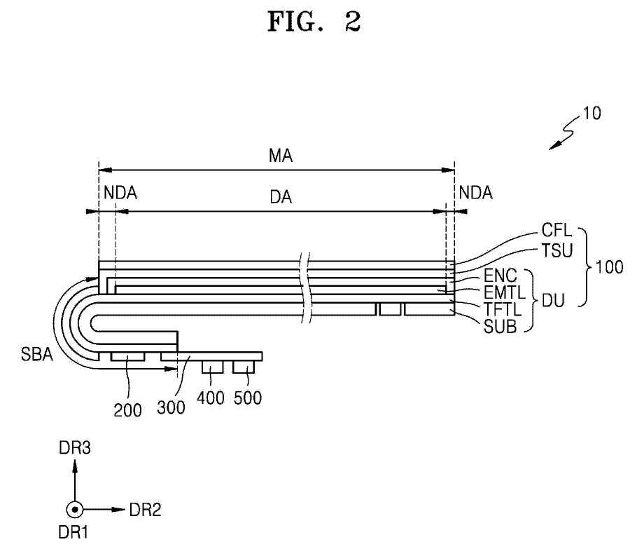

FIG. 2 is a cross-sectional view of a display device according to an embodiment.

Referring to FIG. 2, the display panel 100 may include a display unit (e.g., a display or a display layer) DU, a touch sensing unit (e.g., a touch sensor or a touch sensing layer) TSU, and a color filter layer CFL. The display unit DU may include a substrate SUB, a thin-film transistor layer TFTL, a light-emitting element layer EMTL, and an encapsulation layer ENC.

The substrate SUB may correspond to a base substrate or a base member. The substrate SUB may include a flexible substrate capable of bending, folding, rolling, and/or the like. For example, the substrate SUB may include, but is not limited to, a polymer resin such as polyimide (PI). For example, the substrate SUB may include a glass material or a metal material.

The thin-film transistor layer TFTL may be arranged on the substrate SUB. The thin-film transistor layer TFTL may include a plurality of thin-film transistors that constitute pixel circuitry of the pixels. The thin-film transistor layer TFTL may further include gate lines, data lines, power lines, gate control lines, fan-out lines connecting the display driver 200 to the data lines, and lead lines connecting the display driver 200 to a pad unit. Each of the thin-film transistors may include a semiconductor region, a source electrode, a drain electrode, and a gate electrode. For example, when a gate driver is formed in one side of the non-display area NDA of the display panel 100, the gate driver may include thin-film transistors.

The thin-film transistor layer TFTL may be arranged across the display area DA, the non-display area NDA, and the sub-area SBA. The thin-film transistors, the gate lines, the data lines, and the power lines of the pixels of a thin-film transistor layer TFTL may be arranged in the display area DA. The gate control lines and the fan-out lines of the thin-film transistor layer TFTL may be arranged in the non-display area NDA. The lead lines of the thin-film transistor layer TFTL may be arranged in the sub-area SBA.

The light-emitting element layer EMTL may be arranged on the thin-film transistor layer TFTL. The light-emitting element layer EMTL may include a plurality of light-emitting elements for emitting light, and a pixel defining film defining the pixels. A pixel electrode, a light-emitting layer, and a common electrode may be sequentially stacked in each of the light-emitting elements. The light-emitting elements of the light-emitting element layer EMTL may be arranged in the display area DA.

For example, a light-emitting layer may include an organic light-emitting layer including an organic material. The light-emitting layer may include a hole transporting layer, an organic light-emitting layer, and an electron transporting layer. When a pixel electrode receives a voltage through a thin film transistor of the thin-film transistor layer TFTL, and a common electrode receives a cathode voltage, a hole and an electron may move to the organic light-emitting layer through the hole transporting layer and the electron transporting layer, respectively, and may combine with each other in the organic light-emitting layer to emit light. For example, the pixel electrode may correspond to an anode electrode, and the common electrode may correspond to a cathode electrode, but the present disclosure is not limited thereto.

For example, a plurality of light-emitting elements may include a quantum dot LED including a quantum dot light-emitting layer, an inorganic LED including an inorganic semiconductor, or a micro LED.

The encapsulation layer ENC may cover top and side surfaces of the light-emitting element layer EMTL, and may protect the light-emitting element layer EMTL. The encapsulation layer ENC may include at least one inorganic film and at least one organic film for encapsulating the light-emitting element layer EMTL.

The touch sensing unit TSU may be placed on the encapsulation layer ENC. The touch sensing unit TSU may include a plurality of touch electrodes for detecting a user's touch by using a capacitance method, and touch lines that connect the touch electrodes to the touch driver 400. For example, the touch sensing unit TSU may sense a user's touch by using a mutual capacitance method or a self-capacitance method.

For example, the touch sensing unit TSU may be arranged on a separate substrate that is arranged on the display unit DU. In this case, the substrate supporting the touch sensing unit TSU may correspond to a base member encapsulating the display unit DU.

The touch electrodes of the touch sensing unit TSU may be arranged in a touch sensor region overlapping with the display area DA. The touch lines of the touch sensing unit TSU may be arranged in a touch peripheral region overlapping with the non-display area NDA.

The color filter layer CFL may be arranged on the touch sensing unit TSU. The color filter layer CFL may include a plurality of color filters corresponding to a plurality of light-emitting regions, respectively. Each color filter may selectively transmit light of a suitable wavelength (e.g., a specific or predetermined wavelength), and block or absorb light of other wavelengths. The color filter layer CFL may absorb some of the light coming from the outside of the display device 10, thereby reducing reflected light of external light. Therefore, the color filter layer CFL may prevent or substantially prevent a color distortion due to external light reflection.

As the color filter layer CFL may be arranged directly on the touch sensing unit TSU, the display device 10 may not include a separate substrate for the color filter layer CFL. Accordingly, the thickness of the display device 10 may be relatively reduced.

The sub-area SBA of the display panel 100 may extend from one side of the main area MA. The sub-area SBA may include a flexible material capable of bending, folding, and/or rolling. For example, when the sub-area SBA is bent, the sub-area SBA may overlap with the main area MA in the thickness direction (e.g., the third direction DR3). The sub-area SBA may include a pad unit electrically connected to the display driver 200 and the circuit board 300.

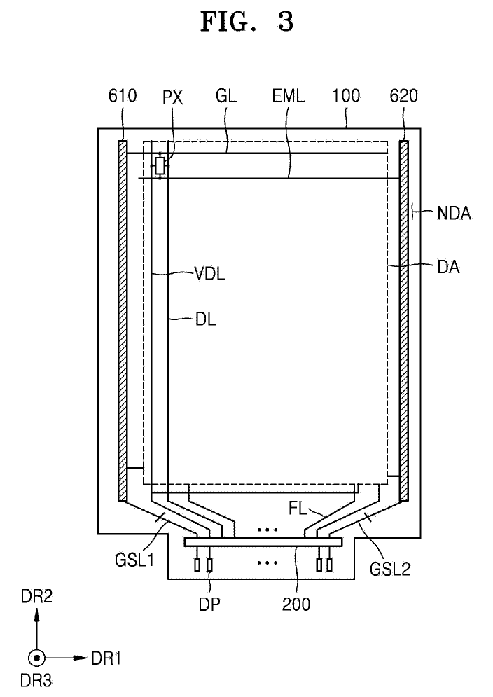

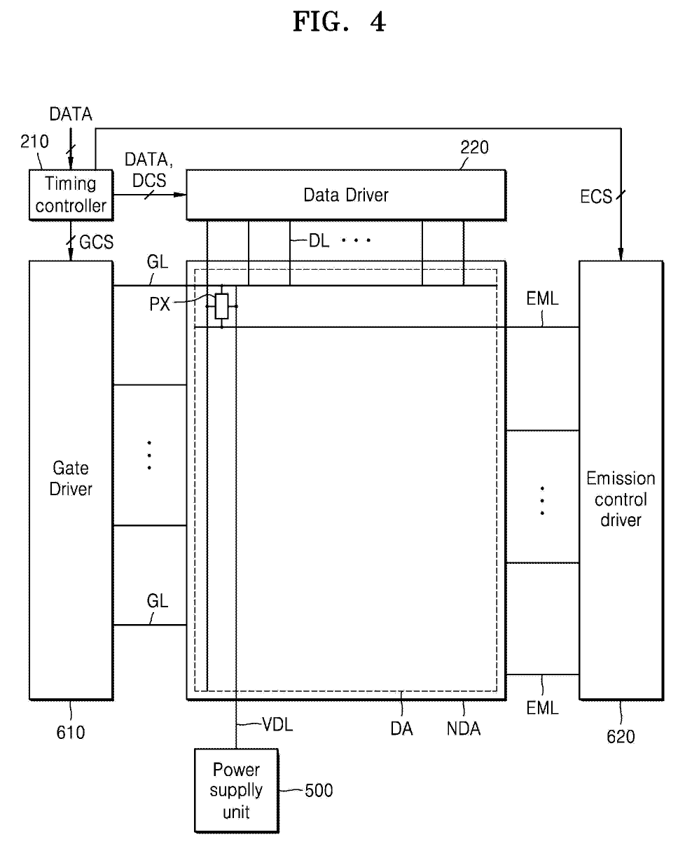

FIG. 3 is a plan view of a display panel of a display device according to an embodiment. FIG. 4 is a block diagram illustrating a display panel and a display driver according to an embodiment.

Referring to FIGS. 3 and 4, the display panel 100 may include a display area DA and a non-display area NDA.

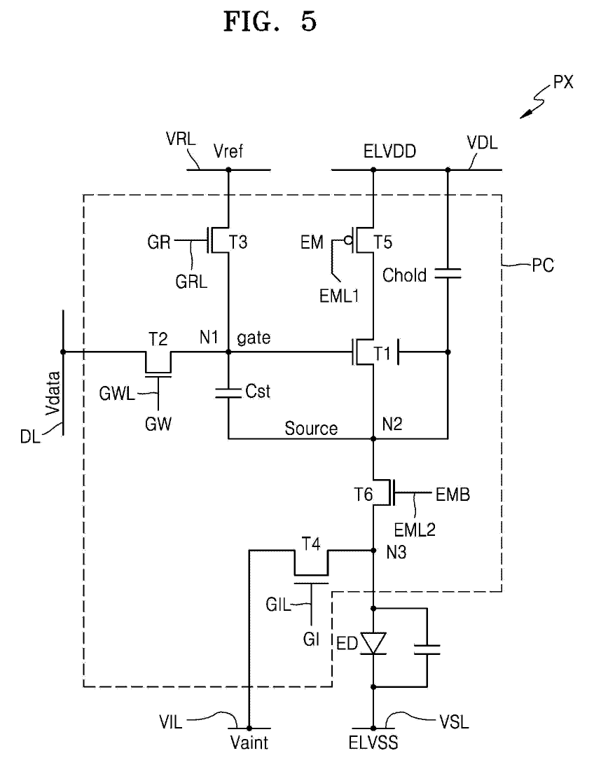

The display area DA may include a plurality of pixels PX, a plurality of driving voltage lines VDL connected to the plurality of pixels PX, a plurality of gate lines GL, a plurality of common voltage lines (e.g., VSL in FIG. 5), a plurality of emission control lines EML, and a plurality of data lines DL. Here, a pixel PX may correspond to a sub-pixel.

Each of the plurality of pixels PX may be connected to a gate line GL, a data line DL, an emission control line EML, a driving voltage line VDL, and a common voltage line VSL. Each of the pixels PX may include at least one transistor, a light-emitting element, and a capacitor.

The gate lines GL may extend in the first direction DR1, and may be spaced apart from each other in the second direction DR2 intersecting or crossing the first direction DR1. The gate lines GL may be arranged in the second direction DR2. The gate lines GL may sequentially supply gate signals to the pixels PX.

The emission control lines EML may extend in the first direction DR1, and may be spaced apart from each other in the second direction DR2. The emission control lines EML may be arranged in the second direction DR2. The emission control lines EML may sequentially provide emission control signals to the pixels PX.

The data lines DL may extend in the second direction DR2, and may be spaced apart from each other in the first direction DR1. The data lines DL may be arranged in the first direction DR1. The data lines DL may supply data voltages to the pixels PX. The data voltages may determine the brightness of each of the pixels PX.

The driving voltage lines VDL may extend in the second direction DR2, and may be spaced apart from each other in the first direction DR1. The driving voltage lines VDL may be arranged in the first direction DR1. The driving voltage lines VDL may provide a first driving voltage ELVDD (e.g., see FIG. 5) to the pixels PX. The first driving voltage ELVDD may include a high-potential voltage for driving the light-emitting elements of the pixels PX.

The non-display area NDA may surround (e.g., around a periphery of) the display area DA. The non-display area NDA may include a gate driver 610, an emission control driver 620, fan-out lines FL, a first gate control line GSL1, and a second gate control line GSL2.

The fan-out lines FL may extend from the display driver 200 to the display area DA. The fan-out lines FL may provide a data voltage received from the display driver 200 to the data lines DL.

The first gate control line GSL1 may extend from the display driver 200 to the gate driver 610. The first gate control line GSL1 may provide a gate control signal GCS received from the display driver 200 to the gate driver 610.

The second gate control line GSL2 may extend from the display driver 200 to the emission control driver 620. The second gate control line GSL2 may provide an emission control signal ECS received from the display driver 200 to the emission control driver 620.

The sub-area SBA may extend from one side of the non-display area NDA. The sub-area SBA may include the display driver 200 and a pad unit (e.g., a pad or a pad terminal) DP. The pad unit DP may be arranged closer to one edge of the sub-area SBA than the display driver 200. The pad unit DP may be electrically connected to the circuit board 300 through an anisotropic conductive film (ACF).

The display driver 200 may include a timing controller 210 and a data driver 220.

The timing controller 210 may receive digital video data DATA and timing signals from the circuit board 300. The timing controller 210 may control the operation timing of the data driver 220 by generating a data control signal DCS based on timing signals, may control an operation timing of the gate driver 610 by generating the gate control signal GCS, and may control an operation timing of the emission control driver 620 by generating the emission control signal ECS. The timing controller 210 may provide the gate control signal GCS to the gate driver 610 through the first gate control line GSL1. The timing controller 210 may provide the emission control signal ECS to the emission control driver 620 through the second gate control line GSL2. The timing controller 210 may provide the digital video data DATA and the data control signal DCS to the data driver 220.

The data driver 220 may convert the digital video data DATA into analog data voltages, and provide the analog data voltages (e.g., the data voltages) to the data lines DL through the fan-out lines FL. Gate signals of the gate driver 610 may select pixels PX to which a data voltage is provided, and the selected pixels PX may receive the data voltage through the data lines DL.

The power supply unit 500 may be arranged on the circuit board 300, and may provide a power supply voltage to the display driver 200 and the display panel 100. The power supply unit 500 may generate and provide a driving voltage to a driving voltage line VDL, generate and provide an initialization voltage to an initialization voltage line, and generate and provide a common voltage to a common electrode that is common to the light-emitting elements of the plurality of pixels PX.

The gate driver 610 may be arranged at an outer side of the display area DA, or at a side of the non-display area NDA. The emission control driver 620 may be arranged at an opposite outer side of the display area DA, or at an opposite side of the non-display area NDA. However, the present disclosure is not limited thereto. For example, the gate driver 610 and the emission control driver 620 may be arranged at either one side or an opposite side of the non-display area NDA.

The gate driver 610 may include a plurality of transistors that generate gate signals based on the gate control signal GCS. The emission control driver 620 may include a plurality of transistors that generate emission control signals based on the emission control signal ECS. For example, the transistors of the gate driver 610 and the transistors of the emission control driver 620 may be formed in the same layer as that of the transistors of the pixels PX. The gate driver 610 may provide gate signals to the gate lines GL, and the emission control driver 620 may provide emission control signals to the emission control lines EML.

FIG. 5 is a circuit diagram of a pixel of a display device according to an embodiment.

A pixel PX may be connected to gate lines including a gate write line GWL, a gate initialization line GIL, and a gate reset line GRL. The pixel PX may be connected to emission control lines including a first emission control line EML1 and a second emission control line EML2, a data line DL, a driving voltage line VDL, a common voltage line VSL, an initialization voltage line VIL, and a reference voltage line VRL.

The pixel PX may include a pixel circuit PC and a light-emitting element ED. The pixel circuit PC may include a first transistor T1, a second transistor T2, a third transistor T3, a fourth transistor T4, a fifth transistor T5, a sixth transistor T6, a first capacitor Cst, and a second capacitor Chold.

In an embodiment, among the first to sixth transistors T1 to T6, the first to fourth transistors T1 to T4 and the sixth transistor T6 may be N-type transistors, and the fifth transistor T5 may be a P-type transistor.

In an embodiment, at least some of the transistors may include an oxide-based active layer, and other transistors may include a silicon-based active layer. For example, each of the first to fourth transistors T1 to T4 and the sixth transistor T6 may include an oxide-based active layer. For example, each of the first to fourth transistors T1 to T4 and the sixth transistor T6 may be an N-type transistor including an active layer including an oxide semiconductor. A transistor including an oxide-based active layer may have a coplanar structure having a gate electrode arranged in an upper portion thereof. The fifth transistor T5 may include a silicon-based active layer. For example, the fifth transistor T5 may be a P-type transistor including an active layer including a low temperature polycrystalline silicon (LTPS).

The first transistor T1 may correspond to a driving transistor that outputs a driving current corresponding to a data signal. The second to sixth transistors T2 to T6 may correspond to switching transistors that transmit signals.

Each of a first terminal (e.g., a first electrode) and a second terminal (e.g., a second electrode) of each of the first to sixth transistors T1 to T6 may correspond to a source electrode or a drain electrode according to the voltage of each of the first terminal and the second terminal. For example, according to the voltages of the first terminal and the second terminal, the first terminal may be a drain electrode and the second terminal may be a source electrode, or the first terminal may be a source electrode and the second terminal may be a drain electrode.

The first transistor T1 may include a gate electrode, a source electrode, and a drain electrode. The first transistor T1 may control a source-drain current (hereinafter, a driving current) according to a data signal (e.g., a data voltage) applied to the gate electrode. The driving current (e.g., I_{sd}) flowing through a channel region of the first transistor T1 may be proportional to the square of the difference between a threshold voltage (e.g., Vₜₕ) and a voltage (e.g., V_{sg}) between the source electrode and the gate electrode of the first transistor T1 (e.g., I_{sd} = k(V_{sg} - Vₜₕ)²). In this case, "k" may be a proportional coefficient determined by the structure and physical characteristics of the first transistor T1, V_{sg} may be the source-gate voltage of the first transistor T1, and Vₜₕ may be the threshold voltage of the first transistor T1.

The light-emitting element ED may receive the driving current (e.g., I_{sd}) and emit light. The amount of light emitted by the light-emitting element ED, or the brightness of the light-emitting element ED, may be proportional to the magnitude of the driving current (e.g., I_{sd}).

The light-emitting element ED may include an organic light-emitting diode including a first electrode, a second electrode, and an organic light-emitting layer between the first electrode and the second electrode. As another example, the light-emitting element ED may include an inorganic light-emitting element including a first electrode, a second electrode, and an inorganic semiconductor between the first electrode and the second electrode. As another example, the light-emitting element ED may include a quantum dot light-emitting element including a first electrode, a second electrode, and a quantum dot light-emitting layer between the first electrode and the second electrode. As another example, the light-emitting element ED may include a micro light-emitting diode.

The first electrode of the light-emitting element ED may be electrically connected to a third node N3. The first electrode of the light-emitting element ED may be connected to the drain electrode of the sixth transistor T6 and the source electrode of the fourth transistor T4 via the third node N3. The second electrode of the light-emitting element ED may be connected to the common voltage line VSL. The second electrode of the light-emitting element ED may receive a common voltage ELVSS (e.g., a low-potential voltage) from the common voltage line VSL.

The second transistor T2 may be turned on by a gate write signal GW of the gate write line GWL, and may electrically connect the data line DL to a first node N1. The drain electrode of the second transistor T2, the first electrode of the first capacitor Cst, and the drain electrode of the third transistor T3 may be connected to the first node N1. The second transistor T2 may be turned on based on the gate write signal GW, thereby providing a data voltage Vdata to the first node N1. The gate electrode of the second transistor T2 may be electrically connected to the gate write line GWL, the source electrode of the second transistor T2 may be electrically connected to the data line DL, and the drain electrode of the second transistor T2 may be electrically connected to the first node N1.

The third transistor T3 may be connected to the gate electrode of the first transistor T1 and the reference voltage line VRL. The third transistor T3 may include a gate connected to the gate reset line GRL, a first terminal connected to the first node N1, and a second terminal connected to the reference voltage line VRL. The first terminal of the third transistor T3 may be connected to the gate electrode of the first transistor T1, the second terminal of the second transistor T2, and the first capacitor Cst. The third transistor T3 may be turned on by a gate reset signal GR transmitted to the gate reset line GRL, and may transmit a reference voltage Vref transmitted to the reference voltage line VRL to the first node N1.

The fourth transistor T4 may be connected to the light-emitting element ED and the initialization voltage line VIL. The fourth transistor T4 may be connected to the sixth transistor T6. The fourth transistor T4 may include a gate connected to the gate initialization line GIL, a first terminal connected to the third node N3, and a second terminal connected to the initialization voltage line VIL. The first terminal of the fourth transistor T4 may be connected to the second terminal of the sixth transistor T6 and the first electrode of the light-emitting element ED. The fourth transistor T4 may be turned on by a gate initialization signal GI transmitted to the gate initialization line GIL, and may transmit an initialization voltage Vaint transmitted to the initialization voltage line VIL to the third node N3.

The fifth transistor T5 may be connected to the driving voltage line VDL and the first transistor T1. The fifth transistor T5 may include a gate connected to the first emission control line EML1, a first terminal connected to the driving voltage line VDL, and a second terminal connected to the first electrode of the first transistor T1. The fifth transistor T5 may be turned on or off according to a first emission control signal EM transmitted to the first emission control line EML1.

The sixth transistor T6 may be connected to the first transistor T1 and the light-emitting element ED. The sixth transistor T6 may be connected between a second node N2 and the third node N3. The sixth transistor T6 may include a gate connected to the second emission control line EML2, a first terminal connected to the second node N2, and a second terminal connected to the third node N3. The first terminal of the sixth transistor T6 may be connected to the second terminal of the first transistor T1, the first capacitor Cst, and the second capacitor Chold. The second terminal of the sixth transistor T6 may be connected to the first electrode of the light-emitting element ED. The sixth transistor T6 may be turned on or off according to a second emission control signal EMB transmitted to the second emission control line EMBL.

The first capacitor Cst may be connected between the gate electrode of the first transistor T1 and the second terminal of the first transistor T1. The first electrode of the first capacitor Cst may be connected to the first node N1, and the second electrode of the first capacitor Cst may be connected to the second node N2. The first electrode of the first capacitor Cst may be connected to the gate electrode of the first transistor T1, the second terminal of the second transistor T2, and the first terminal of the third transistor T3. The second electrode of the first capacitor Cst may be connected to the second terminal of the first transistor T1, the second electrode of the second capacitor Chold, and the first terminal of the sixth transistor T6. The first capacitor Cst may correspond to a storage capacitor that stores the threshold voltage of the first transistor T1 and a voltage corresponding to the data signal Vdata.

The second capacitor Chold may be connected between the driving voltage line VDL and the second node N2. The first electrode of the second capacitor Chold may be connected to the driving voltage line VDL. The second electrode of the second capacitor Chold may be connected to the second terminal of the first transistor T1, the second electrode of the first capacitor Cst, and the first terminal of the sixth transistor T6. The capacitance of the first capacitor Cst may be greater than the capacitance of the second capacitor Chold.

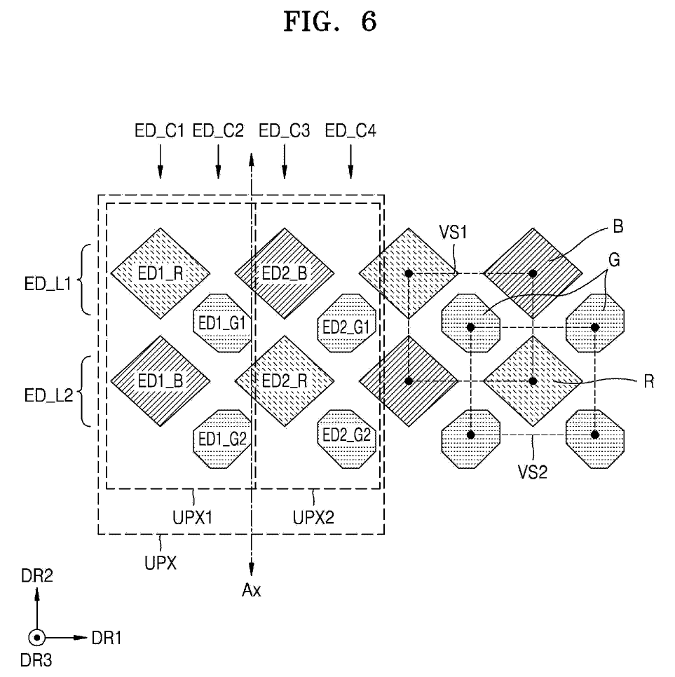

FIG. 6 is a plan view illustrating an arrangement of light-emitting elements of a display device according to an embodiment.

Referring to FIG. 6, the display device 10 according to an embodiment may include a plurality of pixel units (e.g., a plurality of unit pixel areas) UPX that are repeatedly arranged in a matrix. One pixel unit UPX may include a plurality of sub-pixels. For example, one pixel unit UPX may include a total of eight sub-pixels. However, the number of sub-pixels in one pixel unit UPX is not limited thereto. One sub-pixel may include the pixel circuit PC and the light-emitting element ED described above with reference to FIG. 5.

One pixel unit UPX may include a first pixel unit UPX1 and a second pixel unit UPX2, which are adjacent to each other. Each of the first pixel unit UPX1 and the second pixel unit UPX2 may include a plurality of light-emitting elements ED. The first pixel unit UPX1 may include a first red light-emitting element ED1_R, a first-first green light-emitting element ED1_G1, a first blue light-emitting element ED1_B, and a first-second green light-emitting element ED1_G2. The second pixel unit UPX2 may include a second red light-emitting element ED2_R, a second-first green light-emitting element ED2_G1, a second blue light-emitting element ED2_B, and a second-second green light-emitting element ED2_G2.

The light-emitting elements included in the second pixel unit UPX2 may be arranged such that the first pixel unit UPX1 is rotated by 180 degrees clockwise with respect to a virtual axis Ax, which divides the first pixel unit UPX1 from the second pixel unit UPX2, and is then flipped left and right around an axis parallel to or substantially parallel to the virtual axis Ax. Accordingly, the light-emitting elements included in the pixel unit UPX may be arranged in the order of a red light-emitting element R, a green light-emitting element G, a blue light-emitting element B, and a green light-emitting element G in a first light-emitting element row ED_L1, and may be arranged in the order of a blue light-emitting element B, a green light-emitting element G, a red light-emitting element R, and a green light-emitting element G in a second light-emitting element row ED_L2. Accordingly, the light-emitting elements included in the plurality of pixel units UPX may be arranged such that red light-emitting elements R alternate with blue light-emitting elements B in odd-numbered light-emitting element columns including a first light-emitting element column ED_C1 and a third light-emitting element column ED_C3. In the pixel units UPX, only green light-emitting elements G may be arranged in even-numbered light-emitting element columns including a second light-emitting element column ED_C2 and a fourth light-emitting element column ED_C4.

The light-emitting elements included in a pixel unit UPX may be arranged as a diamond shape (e.g., a diamond PENTILE® kind among PENTILE® kinds, PENTILE® being a duly registered trademark of Samsung Display Co., Ltd.). For example, the first-first green light-emitting element ED1_G1 in the first light-emitting element row ED_L1 may be arranged in a diagonal direction, which intersects or crosses the first direction DR1 and the second direction DR2, with respect to the first red light-emitting element ED1_R or the second blue light-emitting element ED2_B in the first light-emitting element row ED_L1. In other words, it may be understood that in the pixel unit UPX, red light-emitting elements R are respectively arranged at first and third vertices diagonally located among the vertices of a first virtual square VS1, which has a center point of a green light-emitting element G as the center point thereof, and blue light-emitting elements B are respectively arranged at remaining vertices (e.g., second and fourth vertices). In other words, it may be understood that green light-emitting elements G are respectively arranged at the vertices of a second virtual square VS2 of which a center point is the center point of a red light-emitting element R or a blue light-emitting element B. However, the first and second virtual squares VS1 and VS2 may be modified into various suitable shapes as needed or desired, such as rectangles, rhombuses, and squares.

In an embodiment, each of a size of the light-emitting region of the red light-emitting element R and a size of the light-emitting region of the blue light-emitting element B may be larger than a size of the light-emitting region of the green light-emitting element G. The size of the light-emitting region of the red light-emitting element R and the size of the light-emitting region of the blue light-emitting element B may be the same or substantially the same as each other, or may be different from each other. The size of the light-emitting region may refer to an area or a width of the light-emitting region on a substrate (e.g., in a plan view).

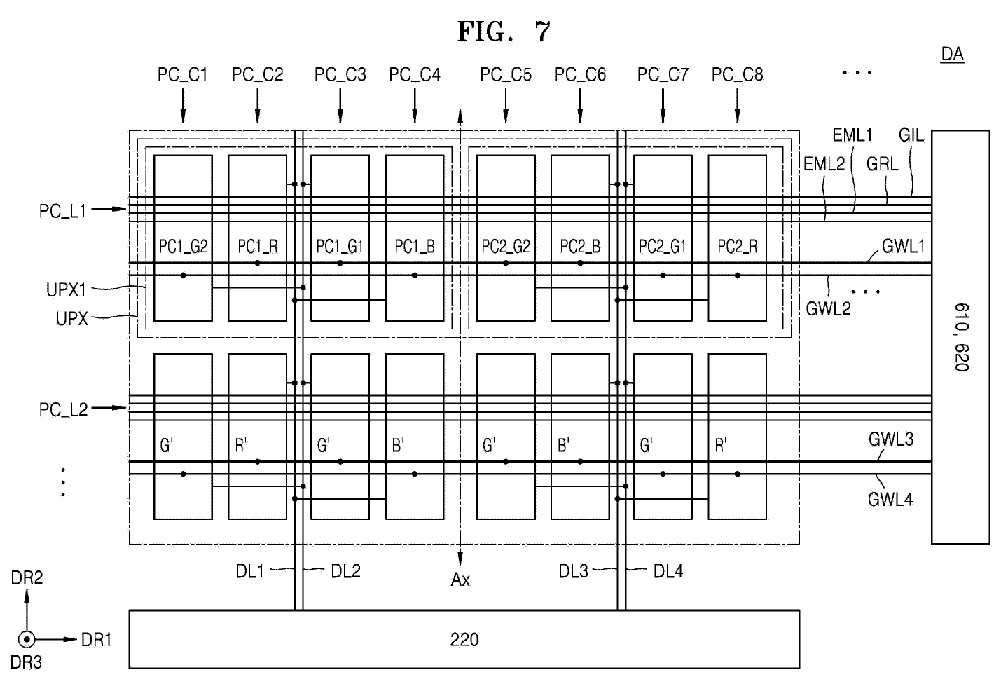

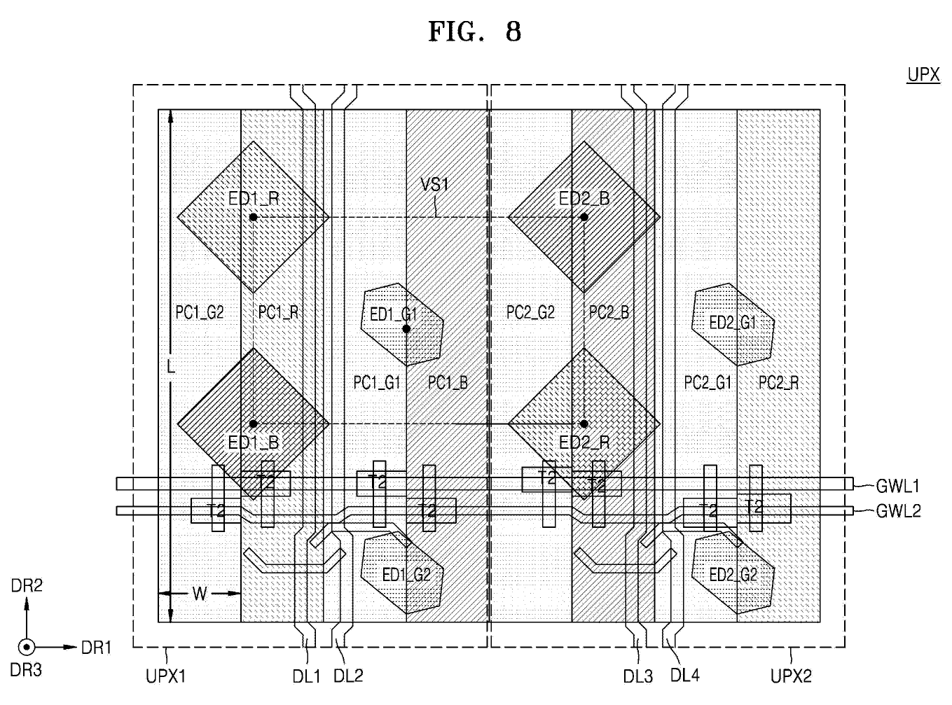

FIG. 7 is a plan view illustrating an arrangement of pixel circuits of a display device according to an embodiment. FIG. 8 is a plan view illustrating both an arrangement of pixel circuits and an arrangement of light-emitting elements in a display device according to an embodiment.

As described above, one pixel unit UPX may include the first pixel unit UPX1 and the second pixel unit UPX2, which are adjacent to each other. Each of the first pixel unit UPX1 and the second pixel unit UPX2 may include a plurality of pixel circuits PC, which are electrically connected to a plurality of light-emitting elements ED to drive the light-emitting elements ED.

Accordingly, the first pixel unit UPX1 may include a first red pixel circuit PC1_R electrically connected to the first red light-emitting element ED1_R, a first-first green pixel circuit PC1_G1 electrically connected to the first-first green light-emitting element ED1_G1, a first blue pixel circuit PC1_B electrically connected to the first blue light-emitting element ED1_B, and a first-second green pixel circuit PC1_G2 electrically connected to the first-second green light-emitting element ED1_G2. The second pixel unit UPX2 may include a second red pixel circuit PC2_R electrically connected to the second red light-emitting element ED2_R, a second-first green pixel circuit PC2_G1 electrically connected to the second-first green light-emitting element ED2_G1, a second blue pixel circuit PC2_B electrically connected to the second blue light-emitting element ED2_B, and a second-second green pixel circuit PC2_G2 electrically connected to the second-second green light-emitting element ED2_G2. Hereinafter, a pixel circuit electrically connected to the red light-emitting element R may be referred to as a red pixel circuit R', a pixel circuit electrically connected to the green light-emitting element G may be referred to as a green pixel circuit G', and a pixel circuit electrically connected to the blue light-emitting element B may be referred to as a blue pixel circuit B'.

The arrangement of the pixel circuits included in the pixel unit UPX may be different from the arrangement of the light-emitting elements in the pixel unit UPX. The pixel circuits included in the pixel unit UPX may be arranged in the order of a green pixel circuit G', a red pixel circuit R', a green pixel circuit G', and a blue pixel circuit B' in a first pixel circuit row PC_L1. The pixel circuits in subsequent pixel circuit rows including a second pixel circuit row PC_L2 may be arranged in the same order as that in the first pixel circuit row PC_L1.

For the pixel circuits included in a plurality of pixel units UPX, only green pixel circuits may be arranged in odd-numbered pixel circuit columns, including a first pixel circuit column PC_C1, a third pixel circuit column PC_C3, a fifth pixel circuit column PC_C5, and a seventh pixel circuit column PC_C7. For the pixel circuits included in the pixel units UPX, only red pixel circuits may be arranged in some pixel circuit columns including a second pixel circuit column PC_C2 and an eighth pixel circuit column PC_C8. For the pixel circuits included in the pixel units UPX, only blue pixel circuits may be arranged in some pixel circuit columns including a fourth pixel circuit column PC_C4 and a sixth pixel circuit column PC_C6.

A plurality of gate write lines (e.g., GWL1, GWL2, GWL3, and GWL4) extending in the first direction DR1 may be arranged on a substrate. A first gate write line GWL1 and a second gate write line GWL2 may be adjacent to each other. The first gate write line GWL1 and the second gate write line GWL2 may cross, in the first direction DR1, the pixel units UPX arranged in a first row. A third gate write line GWL3 and a fourth gate write line GWL4 may be adjacent to each other. The third gate write line GWL3 and the fourth gate write line GWL4 may cross, in the first direction DR1, the pixel units UPX arranged in a second row.

The gate write signal GW may flow through the gate write line GWL (e.g., see FIG. 5). A gate write signal may be sequentially applied to the first gate write line GWL1, the second gate write line GWL2, the third gate write line GWL3, and the fourth gate write line GWL4. For example, a gate write signal may be applied first to the first gate write line GWL1, and then a gate write signal may be applied to the second gate write line GWL2.

Referring to FIG. 7, within the pixel unit UPX, the first red pixel circuit PC1_R, the first-first green pixel circuit PC1_G1, the second blue pixel circuit PC2_B, and the second-second green pixel circuit PC2_G2 may be electrically connected to the first gate write line GWL1. In addition, the first blue pixel circuit PC1_B, the first-second green pixel circuit PC1_G2, the second red pixel circuit PC2_R, and the second-first green pixel circuit PC2_G1 may be electrically connected to the second gate write line GWL2.

The pixel circuit is electrically connected to the light-emitting element. Therefore, in the pixel unit UPX, the first red light-emitting element ED1_R, the first-first green light-emitting element ED1_G1, the second blue light-emitting element ED2_B, and the second-second green light-emitting element ED2_G2 may be electrically connected to the first gate write line GWL1. In addition, the first blue light-emitting element ED1_B, the first-second green light-emitting element ED1_G2, the second red light-emitting element ED2_R, and the second-first green light-emitting element ED2_G1 may be electrically connected to the second gate write lines GWL2. As a connection between the gate write line GWL and the second transistor T2 of the pixel circuit PC has been described above with reference to FIG. 5, redundant description thereof may not be repeated hereinafter.

A plurality of data lines (e.g., DL1, DL2, DL3, and DL4) extending in the second direction DR2 may be arranged on the substrate.

A first data line DL1 and a second data line DL2 may be adjacent to each other. The first data line DL1 may cross at least the first red pixel circuit PC1_R in the second direction DR2. The second data line DL2 may cross at least the first-first green pixel circuit PC1_G1 in the second direction DR2. The first data line DL1 and the second data line DL2 may extend in the second direction DR2 between at least the first red light-emitting element ED1_R and the first blue light-emitting element ED1_B and the first-first green light-emitting element ED1_G1 and the first-second green light-emitting element ED1_G2.

A third data line DL3 and a fourth data line DL4 may be adjacent to each other. The third data line DL3 may cross at least the second blue pixel circuit PC2_B in the second direction DR2. The fourth data line DL4 may cross at least the second-first green pixel circuit PC2_G1 in the second direction DR2. The third data line DL3 and the fourth data line DL4 may extend in the second direction DR2 between the second blue light-emitting element ED2_B and the second red light-emitting element ED2_R and the second-first green light-emitting element ED2_G1 and the second-second green light-emitting element ED2_G2.

The data signal Vdata may flow through the data line DL (e.g., see FIG. 5). Different data signals may be applied to the first data line DL1, the second data line DL2, the third data line DL3, and the fourth data line DL4, respectively.

Referring to FIG. 7, the first red pixel circuit PC1_R and the first blue pixel circuit PC1_B may be electrically connected to the first data line DL1. Accordingly, the first red light-emitting element ED1_R and the first blue light-emitting element ED1_B may emit light in response to a first data signal from the first data line DL1. The first-first green pixel circuit PC1_G1 and the first-second green pixel circuit PC1_G2 may be electrically connected to the second data line DL2. Accordingly, the first-first green light-emitting element ED1_G1 and the first-second green light-emitting element ED1_G2 may emit light in response to a second data signal from the second data line DL2. The second red pixel circuit PC2_R and the second blue pixel circuit PC2_B may be electrically connected to the third data line DL3. Accordingly, the second red light-emitting element ED2_R and the second blue light-emitting element ED2_B may emit light in response to a third data signal from the third data line DL3. The second-first green pixel circuit PC2_G1 and the second-second green pixel circuit PC2_G2 may be electrically connected to the fourth data line DL4. Accordingly, the second-first green light-emitting element ED2_G1 and the second-second green light-emitting element ED2_G2 may emit light in response to a fourth data signal from the fourth data line DL4.

Referring to FIG. 7, the gate initialization line GIL, the gate reset line GRL, the first emission control line EML1, and the second emission control line EML2, which extend in the first direction DR1, may be arranged on the substrate. A single gate initialization line GIL, a single gate reset line GRL, a single first emission control line EML1, and a single second emission control line EML2 may cross the pixel unit UPX in the first direction DR1. A plurality of pixel circuits and a plurality of light-emitting elements included in the pixel unit UPX may be connected in common to the gate initialization line GIL, the gate reset line GRL, the first emission control line EML1, and the second emission control line EML2. A connection relationship between the transistors of the pixel circuit PC and the gate initialization line GIL, the gate reset line GRL, the first emission control line EML1, and the second emission control line EML2 has been described above with reference to FIG. 5, and thus, redundant description thereof may not be repeated hereinafter.

Referring to FIG. 8, according to an embodiment, in the pixel unit UPX on a substrate of the display device 10, an arrangement pattern of a plurality of pixel circuits may be different from an arrangement pattern of a plurality of light-emitting elements on a two-dimensional (2D) plane (e.g., in a plan view).

For example, the pixel circuits of the pixel unit UPX may be arranged in a stripe kind, and the light-emitting elements of the pixel unit UPX may be arranged in a diamond shape (e.g., a PENTILE® kind). In other words, in the pixel unit UPX, red light-emitting elements R may be respectively arranged at the first and third vertices located diagonally from each other among the vertices of the first virtual square VS1 having the center point of a green light-emitting element G as the center point thereof, and blue light-emitting elements B may be respectively arranged at the other vertices (e.g., the second and fourth vertices) of the first virtual square VS1. On the other hand, the pixel circuits may be arranged in the first direction DR1 in the order of a green pixel circuit G', a red pixel circuit R', a green pixel circuit G', a blue pixel circuit B', a green pixel circuit G', a blue pixel circuit B', a green pixel circuit G', and a red pixel circuit R'. In other words, the light-emitting elements may be arranged such that green light-emitting elements G may be respectively arranged at the vertices of the second virtual square VS2 of which the center point is the center point of either a red light-emitting element R or a blue light-emitting element B, but the pixel circuits may be arranged in the first direction DR1 in the order of the green pixel circuit G', the red pixel circuit R', the green pixel circuit G', the blue pixel circuit B', the green pixel circuit G', the blue pixel circuit B', the green pixel circuit G', and the red pixel circuit R'. However, the first and second virtual squares VS1 and VS2 may be modified into various suitable shapes as needed or desired, such as rectangles, rhombuses, and squares.

Accordingly, at least one pixel circuit included in the pixel unit UPX on the substrate and a light-emitting element electrically connected to the pixel circuit may not overlap with each other. For example, as shown in FIG. 8, the first-second green pixel circuit PC1_G2 may not overlap with the first-second green light-emitting element ED1_G2. The first blue pixel circuit PC1_B may not overlap with the first blue light-emitting element ED1_B. The second-second green pixel circuit PC2_G2 may not overlap with the second-second green light-emitting element ED2_G2. The second red pixel circuit PC2_R may not overlap with the second red light-emitting element ED2_R.

The pixel circuits of the pixel unit UPX may be arranged in a row in the first direction DR1. As shown in FIG. 8, a total of eight pixel circuits may be arranged side by side one another in the first direction DR1 in the pixel unit UPX. A pixel circuit area occupied by each pixel circuit in the pixel unit UPX may have a width W in the first direction DR1 and a length L in the second direction DR2 at a ratio of about 1:8. In other words, the pixel circuit area on the substrate may have a rectangular shape that is longer in the second direction DR2.

In general, in a comparative example, pixel circuits and light-emitting elements included in a pixel unit UPX may be arranged in similar manners as each other. For example, when light-emitting elements of the pixel unit UPX are arranged in a diamond shape (e.g., a PENTILE® kind), the pixel circuits electrically connected to the light-emitting elements may respectively overlap with the light-emitting elements. However, in this case, as the number of transistors and the number of wirings increase, an area occupied by a pixel circuit may increase, and it may be difficult to design a high-resolution pixel due to the arrangement of the light-emitting elements corresponding to the pixel circuits.

However, according to some embodiments of the present disclosure, when the arrangement pattern of the pixel circuits of the pixel unit UPX is designed to be different from the arrangement pattern of the light-emitting elements, as shown in FIG. 8, a high-resolution pixel may be designed when compared to a display device according to the comparative example.

In addition, according to some embodiments of the present disclosure, because the pixel circuit area has an elongated rectangular shape as shown in FIG. 8, a total of eight pixel circuits may be arranged side by side one another in the first direction DR1 in the pixel unit UPX, thereby realizing a high-resolution and high-integration pixel design.

In addition, while a pixel circuit area has the width W in the first direction DR1 and the length L in the second direction DR2 at a ratio of about 1:2, according to the comparative example, the pixel circuit area may have the width W in the first direction DR1 and the length L in the second direction DR2 at a ratio of about 1:8, according to some embodiments of the present disclosure. Accordingly, as eight pixel circuits (e.g., a total of eight pixel circuits) may be arranged in a row in the first direction DR1 in the pixel unit UPX, a high-resolution and high-integration pixel design may be provided.

In addition, according to some embodiments of the present disclosure, the gate initialization line GIL, the gate reset line GRL, the first emission control line EML1, and the second emission control line EML2 may be arranged in common in the pixel unit UPX rather than in each sub-pixel, thereby reducing the number of wirings. Accordingly, a high-resolution and high-integration pixel design may be implemented.

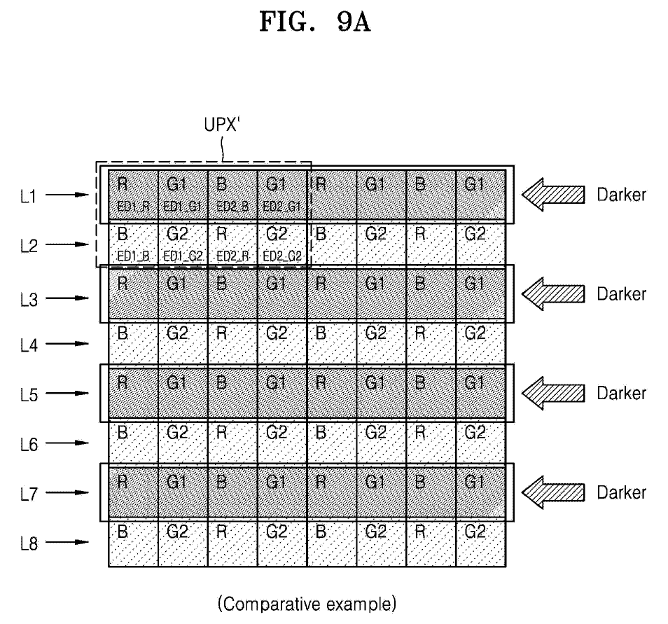

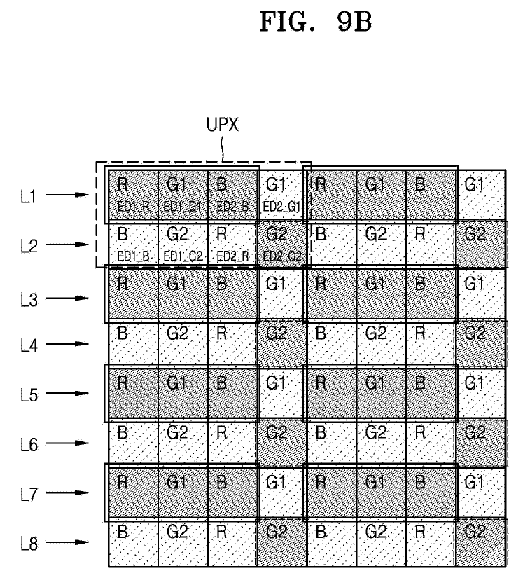

In addition, according to some embodiments of the present disclosure, a difference in brightness between light-emitting element rows may be reduced. In more detail, the brightness difference between an odd row and an even row may be prevented or substantially prevented from occurring due to a secondary kickback issue of the second gate write line GWL2, which may be caused by the first gate write line GWL1 and the second gate write line GWL2 being adjacent to each other across the pixel unit UPX. This will be described in more detail below with reference to FIGS. 9A and 9B.

FIG. 9A schematically illustrates a display area of a display device according to a comparative example. FIG. 9B schematically illustrates a display area of a display device according to an embodiment of the present disclosure.

In FIGS. 9A and 9B, light-emitting elements arranged in a diamond shape (e.g., a PENTILE® kind) are schematically expressed in a matrix format, for convenience of illustration. Therefore, compared to that in FIG. 6, the first light-emitting element row ED_L1 in FIG. 6 may correspond to a first row L1 and a second row L2 in FIGS. 9A and 9B, and the second light-emitting element row ED_L2 in FIG. 6 may correspond to a third row L3 and a fourth row L4 in FIGS. 9A and 9B.

In more detail, FIG. 9A illustrates comparative pixel units UPX' according to the comparative example of a matrix.

In the comparative pixel unit UPX' in the comparative example, the first red light-emitting element ED1_R, the first-first green light-emitting element ED1_G1, the second blue light-emitting element ED2_B, and the second-first green light-emitting element ED2_G1 may be electrically connected to the first gate write line GWL1, and the first blue light-emitting element ED1_B, the first-second green light-emitting element ED1_G2, the second red light-emitting element ED2_R, and the second-second green light-emitting element ED2_G2 may be electrically connected to the second gate write line GWL2. In this case, when a gate signal is applied to the second gate write line GWL2 after the gate signal is applied to the first gate write line GWL1, and data is written to pixel circuits electrically connected to the first gate write line GWL1, a secondary kickback issue may occur due to a coupling effect between the first gate write line GWL1 and the second gate write line GWL2. Due to the secondary kickback issue, an unwanted voltage difference may occur at the first node (e.g., N1 in FIG. 5) of a pixel circuit that is electrically connected to the first gate write line GWL1, which may cause a data value written to the pixel circuit to change. As a result, a brightness of a light-emitting element electrically connected to the first gate write line GWL1 may be lower than a brightness of a light-emitting element electrically connected to the second gate write line GWL2. The light-emitting elements electrically connected to the first gate write line GWL1 may appear relatively darker than the light-emitting elements electrically connected to the second gate write line GWL2.

As shown in FIG. 9A, due to the secondary kickback issue, in the comparative example, the light-emitting elements arranged in odd rows including the first row L1, the third row L3, a fifth row L5, and a seventh row L7 may emit light having a lower brightness than those of the light-emitting elements arranged in even rows including the second row L2, the fourth row L4, a sixth row L6, and an eighth row L8. Therefore, in the comparative example, an improvement in the visibility of the brightness difference between even-row pixels and odd-row pixels may be desired.

In FIG. 9B, the pixel units UPX according to the embodiment described above with reference to FIG. 6 are schematically arranged in a matrix.

The embodiment of FIG. 9B may be different from the comparative example of FIG. 9A, in that in a pixel unit UPX, the second-second green pixel circuit PC2_G2 is electrically connected to the first gate write line GWL1, and the second-first green pixel circuit PC2_G1 is electrically connected to the second gate write line GWL2.

According to some embodiments of the present disclosure, in the pixel unit UPX, the first red light-emitting element ED1_R, the first-first green light-emitting element ED1_G1, the second blue light-emitting element ED2_B, and the second-second green light-emitting element ED2_G2 may be electrically connected to the first gate write line GWL1, and the first blue light-emitting element ED1_B, the first-second green light-emitting element ED1_G2, the second red light-emitting element ED2_R, and the second-first green light-emitting element ED2_G1 may be electrically connected to the second gate write line GWL2. Accordingly, the second-second green light-emitting element ED2_G2 may be electrically connected to the first gate write line GWL1, and the second-first green light-emitting element ED2_G1 may be electrically connected to the second gate write line GWL2, thereby reducing the brightness difference between rows.

In other words, according to an embodiment of the present disclosure, in a pixel unit UPX, the brightness of the second-first green light-emitting element ED2_G1 in a first light-emitting element row (e.g., corresponding to the first row L1 in FIG. 9B) may be higher than the brightness of the remaining light-emitting elements in the first light-emitting element row. In addition, in the pixel unit UPX, the brightness of the second-second green light-emitting element ED2_G2 in the second light-emitting element row (e.g., corresponding to the second row L2 in FIG. 9B) may be lower than the brightness of the remaining light-emitting elements in the second light-emitting element row. In addition, in the pixel unit UPX, the brightness of the second-first green light-emitting element ED2_G1 in the first light-emitting element row (e.g., corresponding to the first row L1 in FIG. 9B) may be higher than the brightness of the second-second green light-emitting element ED2_G2 in the second light-emitting element row (e.g., corresponding to the second row L2 in FIG. 9B). Therefore, because the positions of the pixels having a lower brightness are dispersed compared to those of the comparative example, even when a secondary kickback issue occurs, the visibility of the brightness difference between even-row pixels and odd-row pixels may be improved.

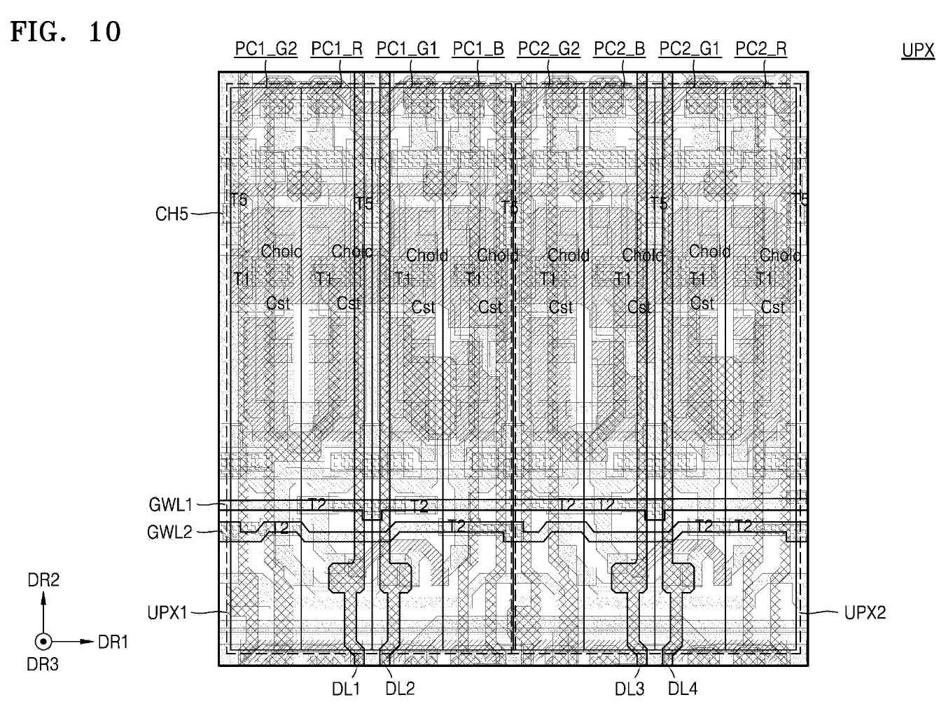

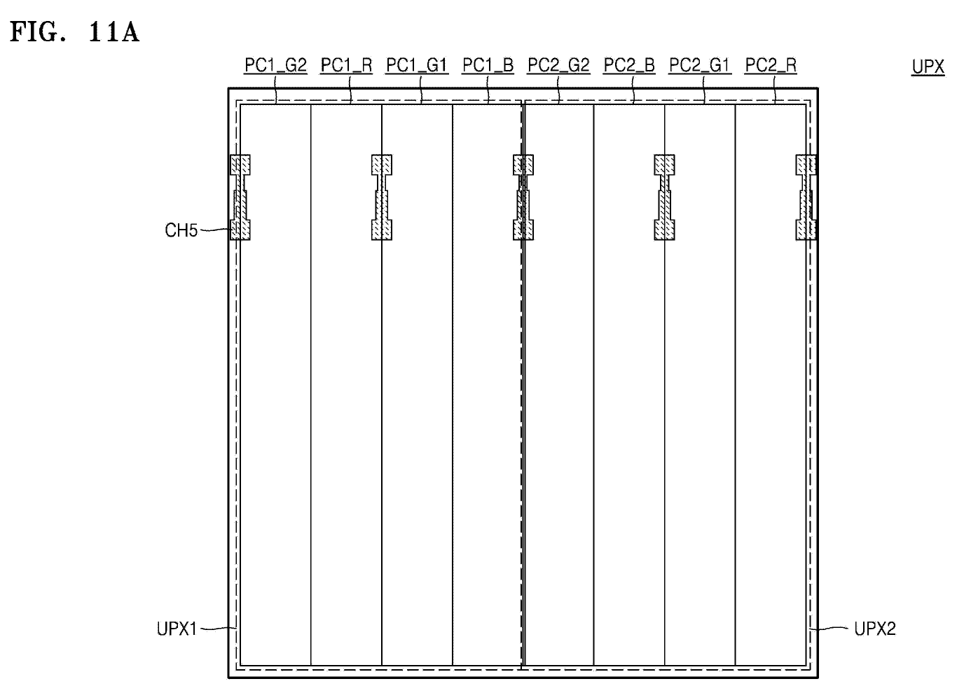

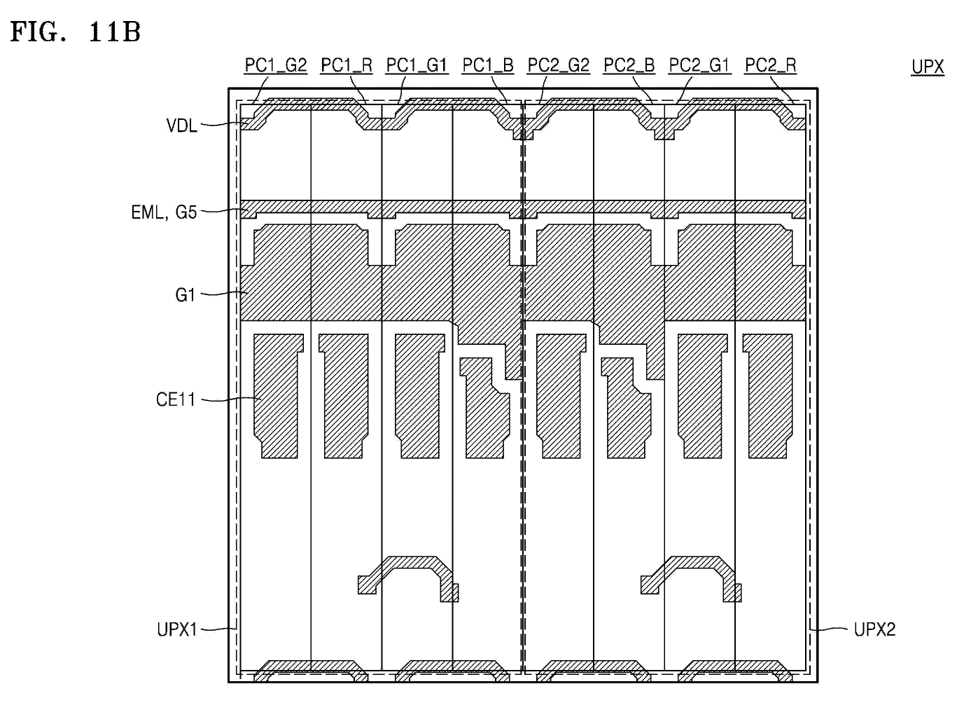

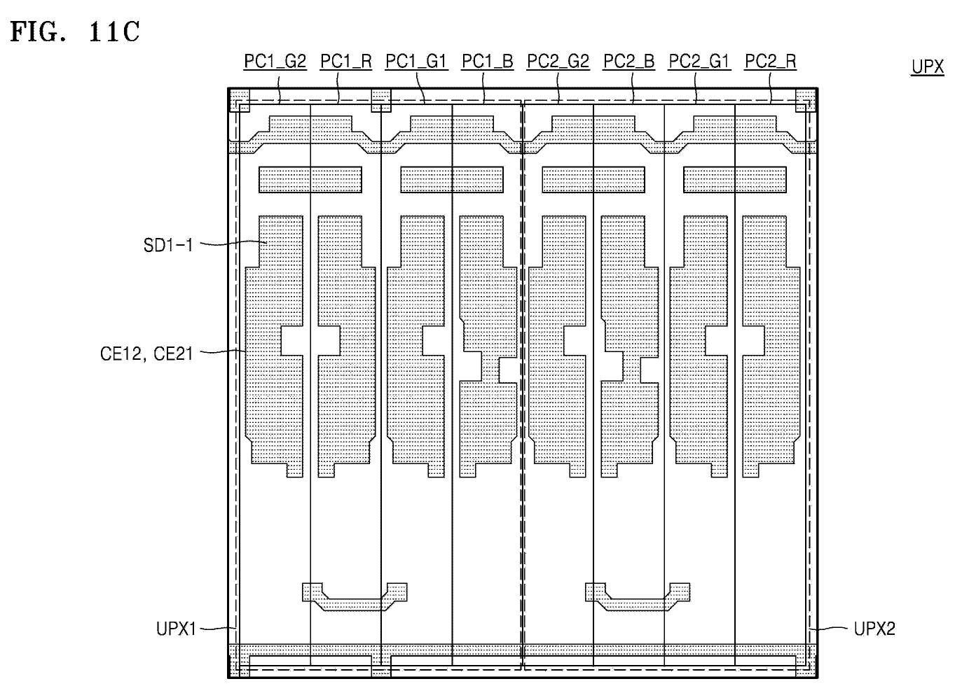

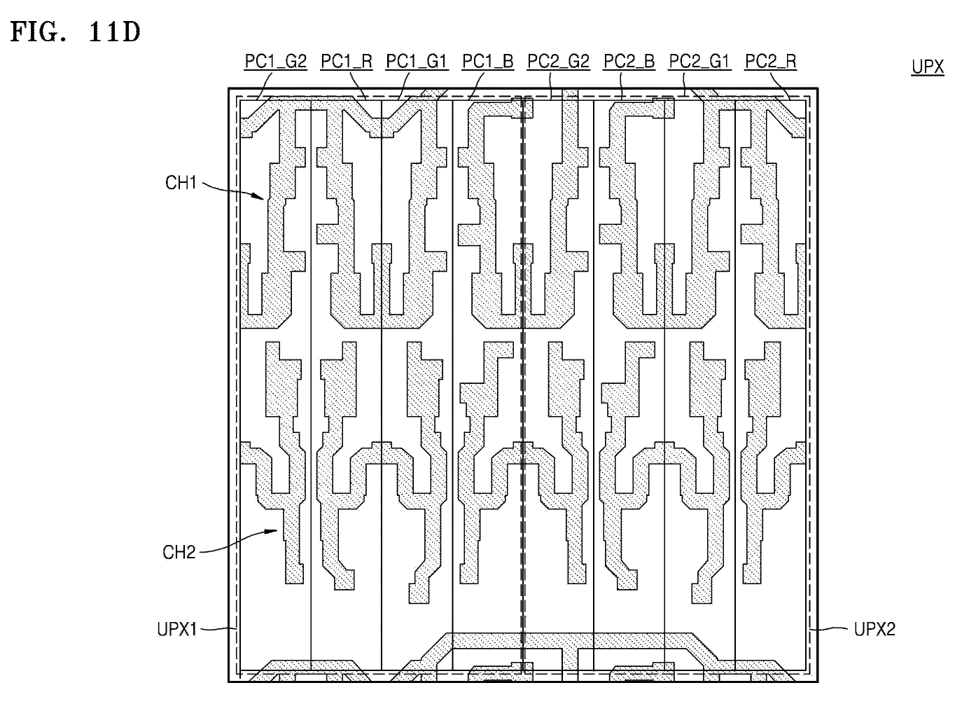

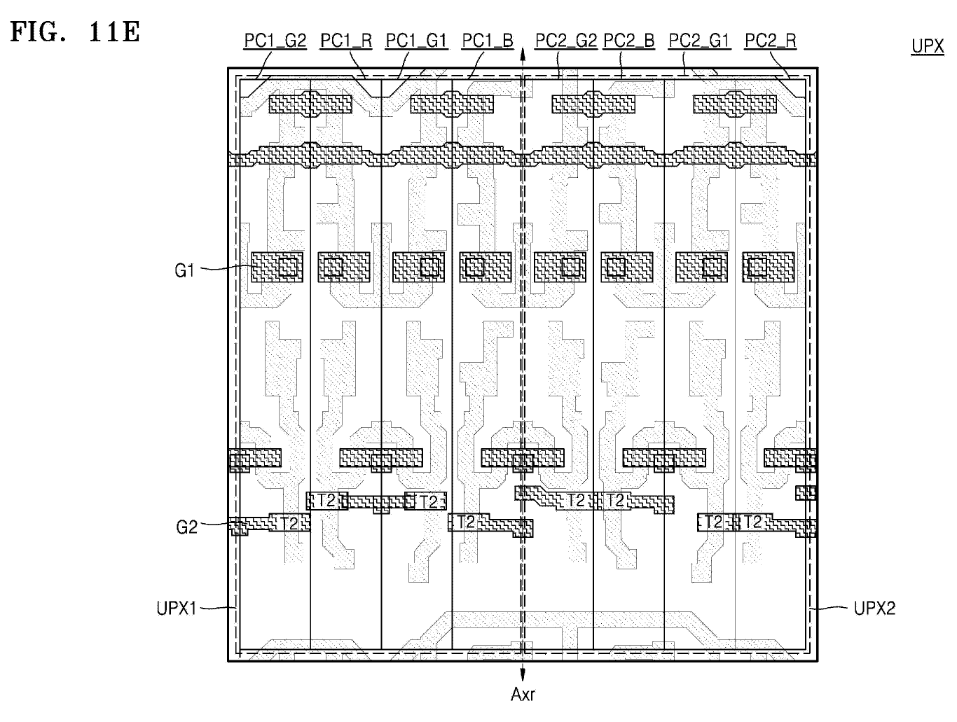

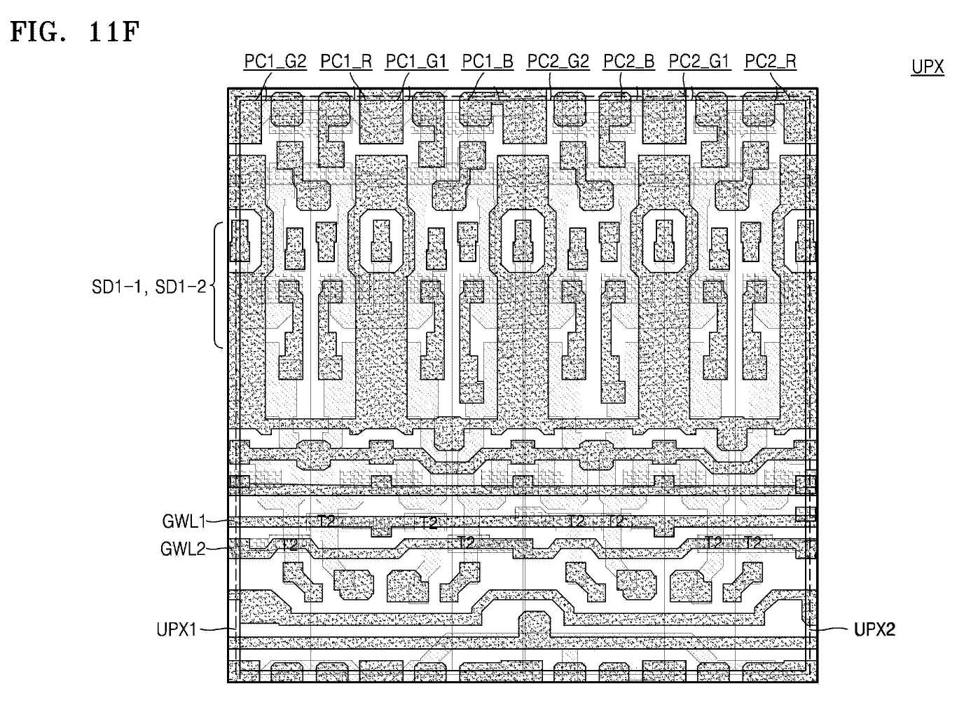

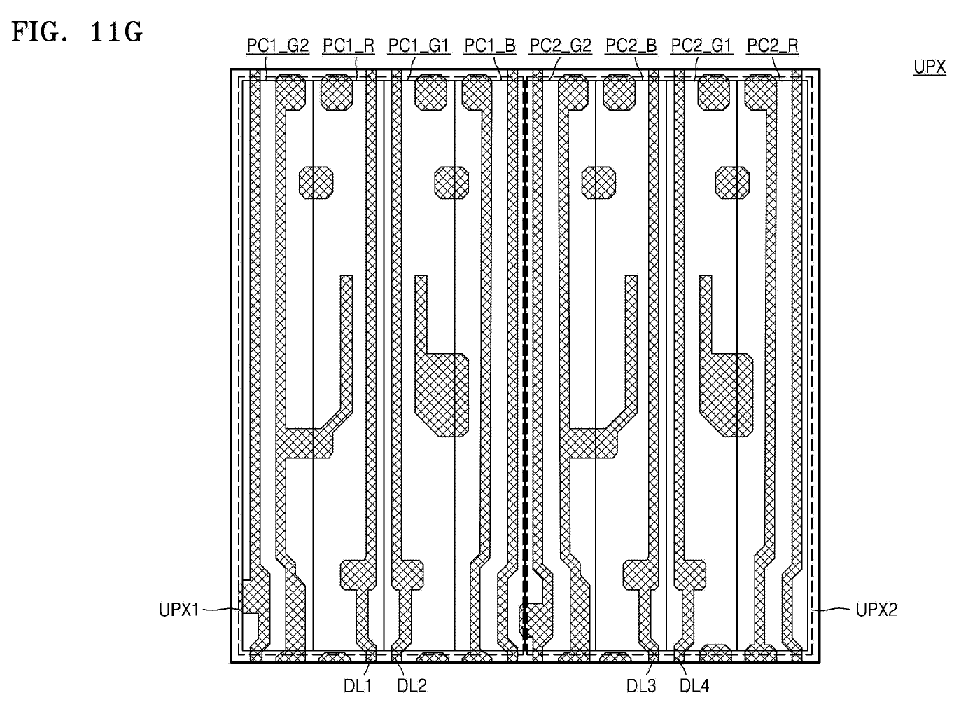

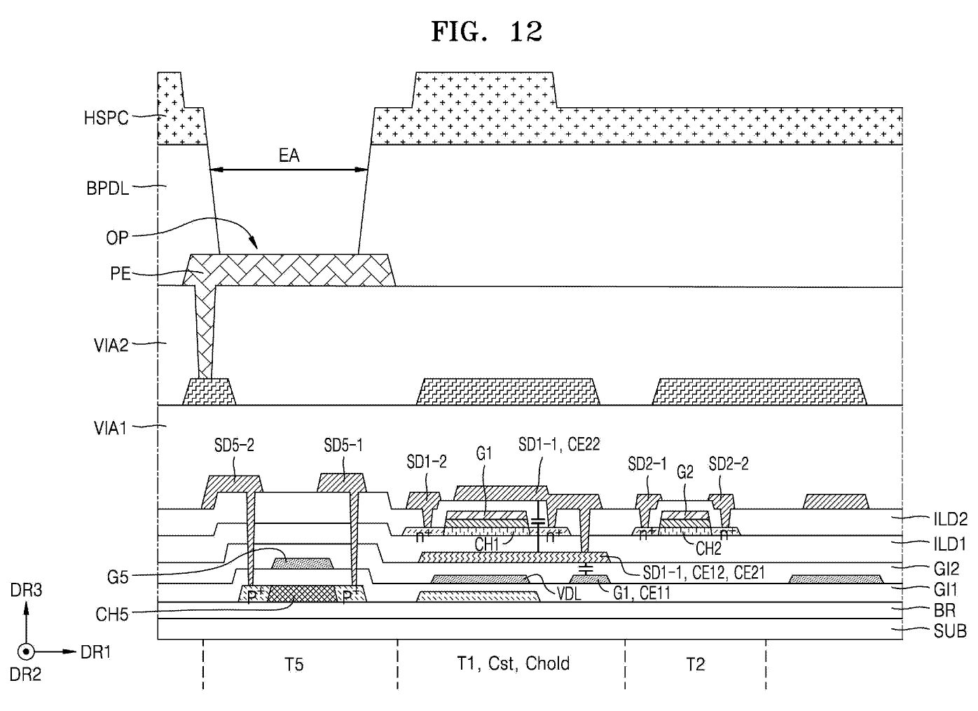

FIG. 10 is a schematic plan view illustrating pixel circuits included in a pixel unit of FIG. 8 according to an embodiment of the present disclosure. For convenience of illustration, the light-emitting elements are not shown in FIG. 10. FIG. 11A is a plan view illustrating a first active layer among the components in FIG. 10. FIG. 11B is a plan view illustrating a first gate layer among the components in FIG. 10. FIG. 11C is a plan view illustrating a second gate layer among the components in FIG. 10. FIG. 11D is a plan view illustrating a second active layer among the components in FIG. 10. FIG. 11E is a plan view illustrating the second active layer and a third gate layer among the components in FIG. 10. FIG. 11F is a plan view illustrating the third gate layer and a first source/drain layer among the components in FIG. 10. FIG. 11G is a plan view illustrating a second source/drain layer among the components in FIG. 10. FIG. 12 is a cross-sectional view illustrating some transistors among the components in FIG. 10. In more detail, FIG. 12 shows the first transistor T1, the second transistor T2, and the fifth transistor T5 among the components of the pixel circuit PC described above with reference to FIG. 5. The cross-sectional view of FIG. 12 may be an illustration including modifications for convenience of illustration of the characteristics of the components.

Hereinafter, the plurality of pixel circuits PC1_G2, PC1_R, PC1_G1, PC1_B, PC2_G2, PC2_B, PC2_G1, and PC2_R, which are included in the pixel unit UPX including the first pixel unit UPX1 and the second pixel unit UPX2, will be described in more detail with reference to FIGS. 10, 11A-11G, and 12. As described above with reference to FIG. 5, each pixel circuit may include a plurality of transistors (e.g., T1 to T6), a plurality of capacitors (e.g., Cst and Chold), and a wiring. In FIG. 10, FIGS. 11A-11G, and 12, the first transistor T1, the second transistor T2, the fifth transistor T5, and the first capacitor Cst are illustrated in more detail.

The first transistor T1 may include a first gate electrode G1, a 1-1 terminal SD1-1, a 1-2 terminal SD1-2, and a first channel region CH1. The second transistor T2 may include a second gate electrode G2, a 2-1 terminal SD2-1, a 2-2 terminal SD2-2, and a second channel region CH2. The fifth transistor T5 may include a fifth gate electrode G5, a 5-1 terminal SD5-1, a 5-2 terminal SD5-2, and a fifth channel region CH5. First terminals including the 1-1 terminal SD1-1, the 2-1 terminal SD2-1, and the 5-1 terminal SD5-1 may each correspond to any one of the source electrode or the drain electrode of a transistor, and second terminals including the 1-2 terminal SD1-2, the 2-2 terminal SD2-2, or the 5-2 terminal SD5-2 may each correspond to the remaining one of the source electrode or the drain electrode of the transistor. The first capacitor Cst may include a first electrode CE11 and a second electrode CE12. The first electrode CE11 and/or the second electrode CE12 of the first capacitor Cst may be provided in common with the gate electrode or the second electrode of a transistor.

Referring to FIG. 12, various components included in the display unit DU (e.g., see FIG. 2) may be positioned on a substrate SUB. The substrate SUB may include glass, a metal, or a polymer resin.

A buffer layer BR including silicon oxide, silicon nitride, or silicon oxynitride may be positioned on the substrate SUB. The buffer layer BR may planarize or substantially planarize the top surface of the substrate SUB.

Referring to FIG. 11A, the first active layer may be arranged on the substrate SUB in the third direction DR3. The first active layer may provide at least the fifth channel region CH5 of the fifth transistor T5. The first active layer may include a semiconductor layer including a low-temperature polycrystalline silicon (LTPS). A silicon-based transistor may have a higher carrier mobility. Therefore, by implementing the fifth transistor T5, which is positioned between the driving voltage line VDL and the first transistor T1 that is a driving transistor, as a silicon-based transistor, a lower resistance between the driving transistor and the driving voltage line VDL may be maintained so that a power loss may be reduced.

Referring to FIG. 11B, the first gate layer may be arranged on the first active layer in the third direction DR3. The first gate layer may include at least the fifth gate electrode G5 of the fifth transistor T5, the first gate electrode G1 of the first transistor T1, the emission control line EML, the driving voltage line VDL, and the first electrode CE11 of the first capacitor Cst. The fifth gate electrode G5 of the fifth transistor T5 may overlap with the first active layer. The fifth channel region CH5 of the fifth transistor T5 may be formed in an overlapping region between the fifth gate electrode G5 of the fifth transistor T5 and the first active layer.

The first gate layer may include a metal, an alloy, a conductive metal oxide, or a transparent conductive material. For example, the first gate layer may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), or indium zinc oxide (IZO). The first gate layer may have a multi-layered structure.

A first gate insulating film GI1 may be arranged between the first active layer and the first gate layer. The first gate insulating film GI1 may include an inorganic insulating layer including silicon oxide, silicon nitride, silicon oxynitride, aluminum oxide, or the like.

Referring to FIG. 11C, the second gate layer may be arranged on the first gate layer in the third direction DR3. The second gate layer may include at least the 1-1 terminal SD1-1 of the first transistor T1 and the second electrode CE12 of the first capacitor Cst.

The second gate layer may have the same material and structure as those of the first gate layer described above.

A second gate insulating film GI2 may be arranged between the first gate layer and the second gate layer. The second gate insulating film GI2 may have the same material and structure as those of the first gate insulating film GI1 described above.

Referring to FIG. 11D, the second active layer may be arranged on the second gate layer in the third direction DR3. The second active layer may provide at least the first channel region CH1 of the first transistor T1 and the second channel region CH2 of the second transistor T2.

The second active layer may include a semiconductor layer including an oxide semiconductor. For example, the oxide semiconductor may include indium gallium zinc oxide (IGZO), indium zinc oxide (IZO), zinc tin oxide (ZTO), tin oxide (SnO), or zinc oxide (ZnO). An oxide semiconductor transistor may have a higher electron mobility, thereby providing a faster switching speed. Therefore, when at least a switching transistor, such as the second transistor T2, is formed using an oxide semiconductor transistor, a higher refresh rate may be provided, and a signal transmission delay may be minimized or reduced in a high-resolution display.

A first interlayer insulating film ILD1 may be arranged between the second gate layer and the second active layer. The first interlayer insulating film ILD1 may include an inorganic film, for example, such as a silicon nitride film, a silicon oxynitride film, a silicon oxide film, a titanium oxide film, or an aluminum oxide film. The first interlayer insulating film ILD1 may include a plurality of inorganic films.

Referring to FIG. 11E, the third gate layer may be arranged on the second active layer in the third direction DR3. The third gate layer may include at least the first gate electrode G1 of the first transistor T1 and the second gate electrode G2 of the second transistor T2.

The third gate layer may have the same material and structure as those of the first gate layer described above.

At least an insulating film, which may be patterned according to the shapes of the first gate electrode G1 and the second gate electrode G2, may be arranged between the second active layer and the third gate layer.

Referring to FIG. 11F, the first source/drain layer may be arranged on the third gate layer in the third direction DR3. The first source/drain layer may include at least the 1-1 terminal SD1-1 and the 1-2 terminal SD1-2 of the first transistor T1, the first gate write line GWL1, and the second gate write line GWL2. The first gate write line GWL1 and the second gate write line GWL2 may extend in the first direction DR1, and may be adjacent to each other in the second direction DR2. Accordingly, because a coupling may occur between the two wirings, a secondary kickback issue may occur in the first gate write line GWL1 when a gate signal is applied to the second gate write line GWL2.

The first source/drain layer may have the same material and structure as those of the first gate layer described above.

A second interlayer insulating film ILD2 may be arranged between the third gate layer and the first source/drain layer. The second interlayer insulating film ILD2 may have the same material and structure as those of the first interlayer insulating film ILD1 described above.

According to an embodiment of the present disclosure, the first pixel unit UPX1 and the second pixel unit UPX2 may respectively have structures that are generally symmetrical with each other with respect to a reference axis Axr that extends between the first pixel unit UPX1 and the second pixel unit UPX2, but at least second gate electrodes G2 of the third gate layer may not be symmetrical with each other with respect to the reference axis Axr. This is because the green pixels included in the first pixel unit UPX1 and the green pixels included in the second pixel unit UPX2 may be connected to gate write lines in different manners from each other. The first-second green light-emitting element ED1_G2 (e.g., see FIG. 8) included in the first pixel unit UPX1 may be connected to the second gate write line GWL2, while the second-second green light-emitting element ED2_G2 (e.g., see FIG. 8) included in the second pixel unit UPX2 may be connected to the first gate write line GWL1. In more detail, referring to FIG. 11F, the second gate electrode G2 of the first-second green pixel circuit PC1_G2 may be connected to the second gate write line GWL2, and the second gate electrode G2 of the second-second green pixel circuit PC2_G2 may be connected to the first gate write line GWL1. In addition, the first-first green light-emitting element ED1_G1 (e.g., see FIG. 8) included in the first pixel unit UPX1 may be connected to the first gate write line GWL1, while the second-first green light-emitting element ED2_G1 included in the second pixel unit UPX2 may be connected to the second gate write line GWL2. In more detail, referring to FIG. 11F, the second gate electrode G2 of the first-first green pixel circuit PC1_G1 may be connected to the first gate write line GWL1, while the second gate electrode G2 of the second-first green pixel circuit PC2_G1 may be connected to the second gate write line GWL2.

Referring to FIG. 11G, the second source/drain layer may be arranged on the first source/drain layer in the third direction DR3. The second source/drain layer may include at least the first data line DL1, the second data line DL2, the third data line DL3, and the fourth data line DL4.

The second source/drain layer may have the same material and structure as those of the first source/drain layer described above.

A first planarization film VIA1 may be arranged between the first source/drain layer and the second source/drain layer. The first planarization film VIA1 may include an organic film, such as an acrylic resin film, an epoxy resin film, a phenolic resin film, a polyamide resin film, or a polyimide resin film.

A second planarization film VIA2 may be arranged on the second source/drain layer. The second planarization film VIA2 may have the same material and structure as those of the first planarization film VIA1 described above.

Referring to FIG. 12, a pixel electrode PE may be arranged on the second planarization film VIA2. A pixel defining film BPDL that defines a light-emitting region may be arranged on the pixel electrode PE. The pixel defining film BPDL may correspond to a black pixel defining layer. A portion of the pixel electrode PE may be exposed by an opening region OP of the pixel defining film BPDL. The opening region OP may be defined as a light-emitting region EA.

An organic light-emitting layer may be further arranged on the pixel electrode PE corresponding to the light-emitting region EA. A common electrode may be further arranged on the organic light-emitting layer. An insulating film HSPC defining a bank may be further arranged on the pixel defining film BPDL.

According to an embodiment, the display device 10 may be applied to any one of various suitable electronic devices 1000. An electronic device according to an embodiment may include the display device 10 described above, and may further include a module or a device having additional functions.

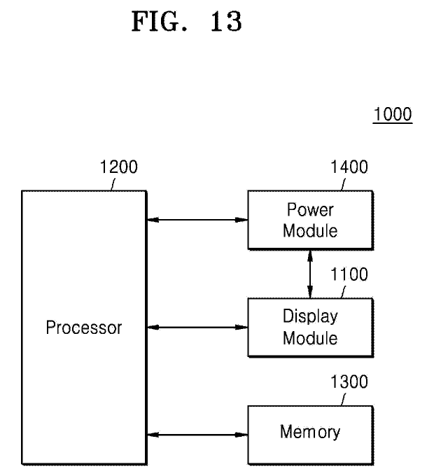

FIG. 13 is a block diagram of an electronic device 1000 according to an embodiment.

Referring to FIG. 13, according to an embodiment, the electronic device 1000 may include a display module (e.g., a display or a touch-display) 1100, a processor 1200, a memory 1300, and a power module (e.g., a power circuit) 1400.

The processor 1200 may include at least one of a central processing unit (CPU), an application processor (AP), a graphics processing unit (GPU), a communication processor (CP), an image signal processor (ISP), and/or a controller.

The controller may output various control signals for driving the display module 1100. For example, the controller may apply various signals to the pixel circuits included in the thin-film transistor layer TFTL. In more detail, the controller may transmit a gate control signal to the gate driver 610 (e.g., see FIG. 4), so that the gate driver 610 may output gate signals to the pixel circuits in response to the gate control signal. The controller may transmit a control signal to the data driver 220 (e.g., see FIG. 4) of the display driver 200 (e.g., see FIG. 2), so that the data driver 220 may convert image data into an analog voltage (e.g., a data voltage) in response to the control signal, and may output data voltages to the pixel circuits.

Data information used for the operation of the processor 1200 or the display module 1100 may be stored in the memory 1300. When the processor 1200 executes an application stored in the memory 1300, an image data signal and/or an input control signal may be transmitted to the display module 1100, and the display module 1100 may process the received signal to output image information through a display screen.

The power module 1400 may include a power supply module, such as a power adapter or a battery device, and a power conversion module that converts power supplied by the power supply module to generate power used for the operation of the electronic device 1000. For example, the power module 1400 may supply power to the controller, enabling the controller to operate.

At least one of the components of the electronic device 1000 described above may be included in the display device according to some of the embodiments described above. Some of the individual modules, which are functionally included in a single module, may be included in the display device, and other individual modules may be provided separately from the display device. For example, the display device may include the display module 1100, and the processor 1200, the memory 1300, and the power module 1400 may be provided as another device in the electronic device 1000 other than the display device.

The electronic or electric devices and/or any other relevant devices or components according to embodiments of the present disclosure described herein may be implemented utilizing any suitable hardware, firmware (e.g. an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the example embodiments of the present disclosure.

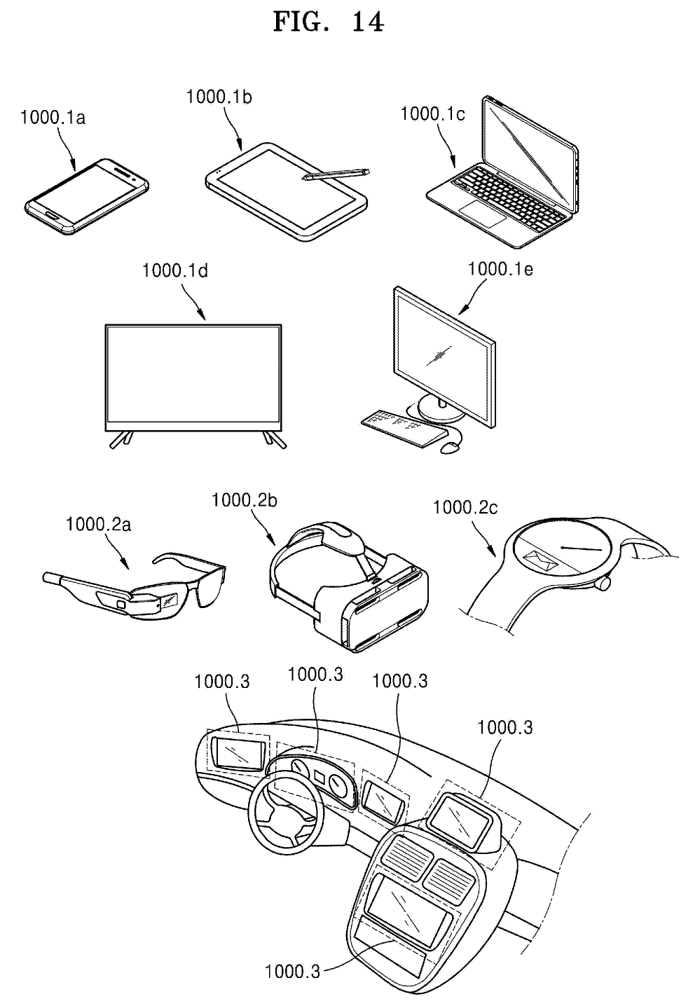

FIG. 14 is a schematic diagram illustrating some electronic devices according to some embodiments.

Referring to FIG. 14, various electronic devices to which a display device according to some embodiments may be applied may include image display electronic devices, such as a smart phone 1000.1a, a tablet PC 1000.1b, a laptop computer 1000.1c, a television (TV) 1000.1d, and a desk monitor 1000.1e, wearable electronic devices, such as smart glasses 1000.2a, an HMD 1000.2b, and a smart watch 1000.2c, each including a display module, and vehicle electronic devices 1000.3, such as a car instrument panel, center fascia, a CID arranged on a dashboard, and a room mirror display, each including a display module.

According to some embodiments of the present disclosure, a display device may reduce the visibility of a difference in brightness by dispersing the positions of sub-pixels having a lower brightness in a pixel unit.

However, the present disclosure is not limited to the above aspects and features, and additional aspects and features not specifically described above may be learned by practicing one or more of the presented embodiments of the present disclosure.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a substrate;
a plurality of pixel units arranged in a matrix on the substrate, each of the plurality of pixel units comprising a plurality of light-emitting elements and a plurality of pixel circuits electrically connected to the light-emitting elements, respectively; and
a plurality of gate write lines on the substrate, and comprising a first gate write line and a second gate write line,
wherein each of the plurality of pixel units comprises a first pixel unit and a second pixel unit adjacent to each other in a first direction,
wherein the first pixel unit comprises a first red light-emitting element, a first-first green light-emitting element, a first blue light-emitting element, and a first-second green light-emitting element from among the plurality of light-emitting elements, the first red light-emitting element and the first-first green light-emitting element being located in a first light-emitting element row, and the first blue light-emitting element and the first-second green light-emitting element being located in a second light-emitting element row,
wherein the second pixel unit comprises a second blue light-emitting element, a second-second green light-emitting element, a second red light-emitting element, and a second-first green light-emitting element from among the plurality of light-emitting elements, the second blue light-emitting element and the second-second green light-emitting element being located in the first light-emitting element row, and the second red light-emitting element and the second-first green light-emitting element being located in the second light-emitting element row,
wherein the first gate write line and the second gate write line are adjacent to each other, and cross each of the plurality of pixel units in the first direction,
wherein the first red light-emitting element, the first-first green light-emitting element, the second blue light-emitting element, and the second-second green light-emitting element are electrically connected to the first gate write line, and
wherein the first blue light-emitting element, the first-second green light-emitting element, the second red light-emitting element, and the second-first green light-emitting element are electrically connected to the second gate write line.

2. The display device of claim 1, wherein, in a plan view, an arrangement pattern of the plurality of light-emitting elements included in each of the plurality of pixel units on the substrate is different from an arrangement pattern of the plurality of pixel circuits included in each of the plurality of pixel units on the substrate.

3. The display device of claim 2, wherein an arrangement of the light-emitting elements included in the second pixel unit corresponds to an arrangement of the light-emitting elements included in the first pixel unit that is rotated by 180 degrees clockwise with respect to a virtual axis, and is then flipped left and right around an axis parallel to the virtual axis, the virtual axis dividing the first pixel unit from the second pixel unit and extending in a second direction crossing the first direction.

4. The display device of claim 2, wherein a green light-emitting element is located at each of vertices of an imaginary square having, as a center point thereof, a center point of a red light-emitting element or a blue light-emitting element in each of the plurality of pixel units.

5. The display device of claim 4, wherein a size of a light-emitting region of each of the red light-emitting element and the blue light-emitting element is larger than a size of a light-emitting region of the green light-emitting element.

6. The display device of claim 2, wherein, in a plan view, at least one pixel circuit included in each of the plurality of pixel units does not overlap with a light-emitting element electrically connected to the at least one pixel circuit.

7. The display device of claim 6, wherein:
the first-second green light-emitting element does not overlap with a first-second green pixel circuit that is electrically connected to the first-second green light-emitting element and configured to drive the first-second green light-emitting element from among the plurality of pixel circuits; and
the second-second green light-emitting element does not overlap with a second-second green pixel circuit that is electrically connected to the second-second green light-emitting element and configured to drive the second-second green light-emitting element from among the plurality of pixel circuits.

8. The display device of claim 2, wherein the plurality of pixel circuits included in each of the plurality of pixel units are located in a row in the first direction.

9. The display device of claim 2, wherein a ratio of a width of a pixel circuit area in the first direction to a length of the pixel circuit area in the second direction is 1:8, the pixel circuit area being occupied by a pixel circuit from among the plurality of pixel circuits included in each of the plurality of pixel units.

10. The display device of claim 1, wherein, in each of the plurality of pixel units, a brightness of the second-first green light-emitting element in the first light-emitting element row is higher than a brightness of remaining light-emitting elements from among the plurality of light-emitting elements in the first light-emitting element row.

11. The display device of claim 1, wherein, in each of the plurality of pixel units, a brightness of the second-second green light-emitting element in the second light-emitting element row is lower than a brightness of remaining light-emitting elements from among the plurality of light-emitting elements in the second light-emitting element row.

12. The display device of claim 1, wherein, in each of the plurality of pixel units, a brightness of the second-first green light-emitting element in the first light-emitting element row is higher than a brightness of the second-second green light-emitting element in the second light-emitting element row.

13. The display device of claim 1, wherein the first gate write line is configured to be applied with a gate write signal first, and the second gate write line is configured to be applied with another gate write signal after the gate write signal is applied to the first gate write line.

14. The display device of claim 1, further comprising:
a plurality of data lines on the substrate, and comprising a first data line configured to transmit a first data signal, a second data line configured to transmit a second data signal, a third data line configured to transmit a third data signal, and a fourth data line configured to transmit a fourth data signal, the first to fourth data lines extending in a second direction crossing the first direction,
wherein, in each of the plurality of pixel units:
the first red light-emitting element and the first blue light-emitting element are configured to emit light in response to the first data signal;
the first-first green light-emitting element and the first-second green light-emitting element are configured to emit light in response to the second data signal;
the second red light-emitting element and the second blue light-emitting element are configured to emit light in response to the third data signal; and
the second-first green light-emitting element and the second-second green light-emitting element are configured to emit light in response to the fourth data signal.

15. The display device of claim 14, wherein:
the first data line and the second data line extend in the second direction at least between the first red light-emitting element and the first blue light-emitting element and the first-first green light-emitting element and the first-second green light-emitting element; and
the third data line and the fourth data line extend in the second direction between the second blue light-emitting element and the second red light-emitting element and the second-first green light-emitting element and the second-second green light-emitting element.

16. The display device of claim 1, further comprising:
a gate initialization line, a gate reset line, a first emission control line, and a second emission control line extending in the first direction on the substrate,
wherein the gate initialization line, the gate reset line, the first emission control line, and the second emission control line are commonly located in the plurality of pixel units.

17. An electronic device comprising:
a substrate;
a plurality of pixel units arranged in a matrix on the substrate, each of the plurality of pixel units comprising a plurality of light-emitting elements and a plurality of pixel circuits electrically connected to the light-emitting elements, respectively;
a plurality of gate write lines on the substrate, and comprising a first gate write line and a second gate write line;
a controller configured to apply a signal to the pixel circuits; and
a power module configured to supply power to the controller,
wherein each of the plurality of pixel units comprises a first pixel unit and a second pixel unit adjacent to each other in a first direction,
wherein the first pixel unit comprises a first red light-emitting element, a first-first green light-emitting element, a first blue light-emitting element, and a first-second green light-emitting element from among the plurality of light-emitting elements, the first red light-emitting element and the first-first green light-emitting element being located in a first light-emitting element row, and the first blue light-emitting element and the first-second green light-emitting element being located in a second light-emitting element row,
wherein the second pixel unit comprises a second blue light-emitting element, a second-second green light-emitting element, a second red light-emitting element, and a second-first green light-emitting element from among the plurality of light-emitting elements, the second blue light-emitting element and the second-second green light-emitting element being located in the first light-emitting element row, and the second red light-emitting element and the second-first green light-emitting element being located in the second light-emitting element row,
wherein the first gate write line and the second gate write line are adjacent to each other, and cross each of the plurality of pixel units in the first direction,
wherein the first red light-emitting element, the first-first green light-emitting element, the second blue light-emitting element, and the second-second green light-emitting element are electrically connected to the first gate write line, and
wherein the first blue light-emitting element, the first-second green light-emitting element, the second red light-emitting element, and the second-first green light-emitting element are electrically connected to the second gate write line.

18. The electronic device of claim 17, wherein, in each of the plurality of pixel units, a brightness of the second-first green light-emitting element in the first light-emitting element row is higher than a brightness of remaining light-emitting elements from among the plurality of light emitting elements in the first light-emitting element row.

19. The electronic device of claim 17, wherein, in each of the plurality of pixel units, a brightness of the second-second green light-emitting element in the second light-emitting element row is lower than a brightness of remaining light-emitting elements from among the plurality of light emitting elements in the second light-emitting element row.

20. The electronic device of claim 17, wherein, in each of the plurality of pixel units, a brightness of the second-first green light-emitting element in the first light-emitting element row is higher than a brightness of the second-second green light-emitting element in the second light-emitting element row.
